(19) United States
(12) Patent Application Publication
(10) Pub. No.: US 2026/0227714 A1
(43) Pub. Date: Aug. 6, 2026

(54) MEASUREMENT SYSTEM, MEASUREMENT METHOD WITH THE AID OF SUCH A MEASUREMENT SYSTEM, AND PROJECTION EXPOSURE APPARATUS COMPRISING SUCH A MEASUREMENT SYSTEM

(71) Applicant: Carl Zeiss SMT GmbH, Oberkochen (DE)

(72) Inventors: Martin ENDRES, Koenigsbronn (DE); Alexander WINKLER, Heidenheim (DE); Robert BUSCHLINGER, Aalen Wasseralfinger (DE)

(21) Appl. No.: 19/634,171

(22) Filed: Mar. 31, 2026

Related U.S. Application Data
(63) Continuation of application No. PCT/EP2024/075911, filed on Sep. 17, 2024.

(30) Foreign Application Priority Data
Oct. 4, 2023 (DE) 10 2023 209 691.9

(51) Int. Cl. G03F 7/00

(52) U.S. Cl. CPC G03F 7/70833; G03F 7/70233; G03F 7/70316

(57) ABSTRACT

A measurement system has two facet mirrors, the individual mirrors of which are tiltable via respective tilting actuator devices, each comprising a tilting actuator. The two facet mirrors are usable as an illumination optical unit of a projection exposure apparatus. Individual mirrors of the second facet mirror are part of a transfer optical unit, by which individual mirrors of the first facet mirror are imageable into an object field illuminated by the illumination optical unit. The measurement system has a measurement light beam selection device, by which a measurement light individual beam is selected which is guided by at least one each of the individual mirrors of the facet mirrors. A detection device of the measurement system detects the measurement light individual beam. A control/regulating device of the measurement system is signal-connected to the tilting actuator devices, the object-field-side measurement light beam selection device and the detection device.

### CROSS-REFERENCE TO RELATED APPLICATIONS

The present application is a continuation of, and claims benefit under 35 USC 120 to, international application No. PCT/EP2024/075911, filed September 17, 2024, which claims benefit under 35 USC 119 of German Application No. 10 2023 209 691.9, filed October 4, 2023. The entire disclosure of each of these applications is incorporated by reference herein.

### FIELD

The disclosure relates to a measurement system comprising two facet mirrors, which mirrors can be used as constituent parts of an illumination optical unit of a microlithographic projection exposure apparatus. Furthermore, the disclosure relates to a measurement method with the aid of such a measurement system, a projection exposure apparatus comprising such a measurement system, a production method for producing a microstructured or nanostructured component with the aid of such a projection exposure apparatus measured by the measurement method, and a microstructured or nanostructured component produced by this method.

### BACKGROUND

A measurement system is known from DE 10 2018 207 384 B4. A metrology system for simulating illumination imaging properties of an optical production system is known from DE 102021213827 A1. A method for characterizing an optical component of a projection exposure apparatus is known from US 2020/0218160 A1. US 8,786,849 B2 discloses a method for measuring an optical system.

### SUMMARY

The present disclosure seeks to provide a measurement system having increased flexibility.

According to the disclosure, it has been recognized that a measurement light beam selection device for predefining at least one measurement light individual beam, which device is signal-connected to tilting actuator devices of the two facet mirrors and the detection device of the measurement system via a control/regulating device, leads to the possibility of flexibly predefining measurement light individual beams for measuring an optical system to which the two facet mirrors belong, in such a way that various optical and/or mechanical parameters for example of the optical assembly having the two facet mirrors can be measured. These include tilt angles of the individual mirrors of the two facet mirrors, which can be calibrated by way of the measurement system depending on the measurement method used, reflection properties of optical components of the optical system to which the two facet mirrors belong, and for example also a far field distribution of a far field of an illumination light source of the projection exposure apparatus. The respective tilting actuator device can have independent tilting actuators respectively assigned to the individual mirrors. The individual mirrors can be micromirrors, for example. The facet mirrors can be embodied as MEMS (microelectromechanical system) mirrors. Alternatively, the individual mirrors of the first facet mirror and/or of the second facet mirror can be monolithic facets, which for their part, for the superimposing guiding of an illumination channel of the illumination optical unit into the object field, are not subdivided into a plurality of individual mirrors.

In an aspect, the disclosure provides a measurement system comprising a first facet mirror comprising individual mirrors which are tiltable by way of at least one first tilting actuator device comprising at least one tilting actuator, and a second facet mirror comprising individual mirrors which are tiltable by way of at least one second tilting actuator device comprising at least one tilting actuator. The two facet mirrors are usable as an illumination optical unit of a projection exposure apparatus, which is used to illuminate an object field with illumination light. An imageable object is arrangeable in the object field. The individual mirrors of the second facet mirror are part of a transfer optical unit, by way of which the individual mirrors of the first facet mirror are imageable into the object field. The measurement system also comprises a measurement light beam selection device, by which at least one measurement light individual beam can be selected which is guided via at least one of the individual mirrors of the first facet mirror and via at least one of the individual mirrors of the second facet mirror. The measurement system further comprises a detection device for detecting the at least one measurement light individual beam. In addition, the measurement device comprises a control/regulating device, which is signal-connected to the tilting actuator devices, the object-field-side measurement light beam selection device and the detection device.

In embodiments, the measurement light beam selection device is embodied such that it can be used to select simultaneously a plurality of measurement light beams which are guided in each case by exactly one individual mirror of the first facet mirror and via in each case at least one individual mirror of the second facet mirror. In such embodiments, a simultaneous measurement of a plurality of measurement light individual beams is possible, and hence a simultaneous measurement of a plurality of individual mirrors of the facet mirrors. Information concerning a corresponding plurality of individual mirrors can thus be obtained by one measurement capture step. At least two measurement light individual beams can be selected simultaneously. The number of simultaneously selectable measurement light individual beams can be in the range of between 2 and 100,000, for example in the range of between 100 and 25,000, for example between 1,000 and 20,000.

The respective measurement light beam can be guided via in each case exactly one individual mirror of the first facet mirror and via in each case exactly one individual mirror of the second facet mirror. Alternatively, it is possible for the respective measurement light beam to be guided via exactly one individual mirror of the first facet mirror and via a plurality of individual mirrors of the second facet mirror, for example via a predefined group of individual mirrors of the second facet mirror. Such a group of individual mirrors of the second facet mirror can have the function of a pupil facet of a pupil facet mirror of a corresponding illumination optical unit. Such a group can include two to e.g. 16 individual mirrors of the second facet mirror, e.g. four individual mirrors of the second facet mirror.

In embodiments, the measurement light beam selection device has at least one reflective micromirror at the location of a measurement field point arranged in the object field. Such embodiments make it possible to capture an illumination angle distribution at a measurement field point at which the micromirror is arranged. The reflective micromirror can then have the function of a pinhole according to a measurement principle which is known from DE 102018207384 B4. As an alternative or in addition to a reflective micromirror, the measurement system can also have a pinhole at the location of the measurement field point. The measurement light beam selection device can also have a plurality of reflective micromirrors and/or pinholes which are correspondingly arranged in a manner distributed over the object field and on which measurement light can impinge by way of corresponding measurement light individual beams. This can increase the flexibility of application of the measurement system. The number of such reflective micromirrors and/or pinholes can be in the range of between 1 and 50.

In embodiments, the measurement light beam selection device is signal-connected to the control/regulating device such that individual mirrors of the first facet mirror and/or individual mirrors of the second facet mirror by which the at least one selected measurement light individual beam is guided are selectable by the measurement light beam selection device. Such embodiments make it possible for example to select measurement support points by predefining corresponding individual mirrors of the first facet mirror in order to capture an intensity distribution over a far field of the light source of the projection exposure apparatus, the first facet mirror being arranged in the far field. Intensity fluctuations of the far field in the arrangement region of the first facet mirror can then be captured, assuming a corresponding distribution of the selected individual mirrors. Such captured far field fluctuations can then be taken into account and compensated for or corrected during operation of the projection exposure apparatus.

In embodiments, the measurement light beam selection device is embodied as an individual mirror group selection device, by way of which groups of individual mirrors of the first facet mirror and/or of the second facet mirror are selectable by which the at least one selected measurement light individual beam is guided. Such embodiments make it possible to correspondingly select groups of individual mirrors for example of the second facet mirror in order to optimize a spatial resolution of an imaging of individual mirrors or first facets of the first facet mirror. The groupwise selection can moreover be chosen so as to avoid channel crosstalk between measurement light individual beams guided via the different individual mirror groups.

In embodiments, the detection device is arranged in the region of the object field. Such embodiments can allow for a measurement independently of an optical unit of the projection exposure apparatus that images the object field. The detection device can be arranged downstream of an object plane or else upstream of an object plane in the beam path of the illumination light. The measurement system can be embodied such that measurement operation in parallel with the used operation of the projection exposure apparatus is possible.

In embodiments, the detection device is arranged in the region of the second facet mirror. Such embodiments can allow for a measurement of optical parameters of the light source of the projection exposure apparatus or else of the first facet mirror.

In embodiments, the measurement system comprises an imaging optical unit for imaging the object field into an image field, wherein the detection device is arranged in the region of the image field. Such embodiments can allow parameters of the imaging optical unit also to be measured, for example imaging properties of the imaging optical unit and/or reflection properties of the mirrors of the imaging optical unit. The imaging optical unit can be embodied usably as a projection optical unit of the projection exposure apparatus.

Depending on the embodiment of the measurement system, the latter can also have a plurality of detection devices arranged in the region of the object field and/or in the region of the second facet mirror and/or in the region of the image field.

In embodiments, the measurement system further comprises a measurement light source. Such embodiments can allow operation of the measurement system independently of the operation of the projection exposure apparatus, for example independently of the operation of the light source of the projection exposure apparatus. Alternatively or additionally, the measurement light source that is used can be a used light source of the projection exposure apparatus, to which the measurement system can belong. The measurement system can have a plurality of measurement light sources. This plurality of measurement light sources can differ in terms of their power or else in terms of their wavelength spectrum. In the case of a plurality of measurement light sources being used, calibration measurements can be realized, for example. Using at least one such calibration measurement, it is possible to simplify an assignment of first individual mirrors to second individual mirrors by way of corresponding measurement light individual beams.

The use of a plurality of measurement light sources can also be used for parallelizing the measurement method and thus e.g. for reducing the measurement time. That is desirable, for example, if a projection exposure apparatus which the measurement system is part of cannot be used productively during the measurement. The use of a plurality of measurement light sources having different measurement light wavelengths can be used to separate detection signals of adjacent individual mirrors from one another by way of differently wavelength-dependently sensitive pixels of the detection device. This, too, makes it possible to parallelize the measurement process. The same is possible by way of a temporal control of a measurement light impingement of the at least one measurement light individual beam for guiding via the individual mirrors. Such a temporal control can lead e.g. to a clocked measurement light impingement, wherein in the case of a plurality of measurement light sources being used, a different temporal control can be effected, which in turn enables a parallel readout of measurement light individual beams which are guided by way of the differently clocked measurement light sources.

In alternative arrangements of the measurement system, the detection device at one end and the measurement light source at the other end can be arranged in a spatially interchanged manner, such that an optical system comprising the two facet mirrors is impinged on by the measurement light in the opposite direction of an actual measurement light beam path. This can enable additional optical and/or mechanical parameters of the facet mirrors, for example of the second facet mirror, to be captured by the measurement system.

In an aspect, the disclosure provides a measurement method that comprises providing a measurement system according to the disclosure, selecting a set of measurement light individual beams using the measurement light beam selection device, and capturing the at least one measurement light beam individual beam using the detection device. The features of such a measurement method can correspond to those which have been explained above with reference to the measurement system.

During capturing, exactly one measurement light individual beam of the selected set can be captured. It is also possible for a plurality of measurement light individual beams to be captured sequentially during capturing. In a further variant, a plurality of measurement light individual beams can be captured in parallel during capturing. The detection device can have a sensor array. Such a sensor array can be embodied as an NxM array of sensor pixels, where N and M independently of one another can be in the range of between 1 and 10,000.

Capturing the at least one measurement light individual beam using the detection device of the measurement system can be followed by evaluating the capture result. Depending on that, operation of the projection exposure apparatus can be controlled, for example for compensation and/or correction of target/actual deviations of measured parameters.

In embodiments of a measurement method, the set of the measurement light individual beams is selected such that the measurement light individual beams impinge on individual mirrors of the first facet mirror which are arranged in a manner distributed over a predefined region of the first facet mirror. Such embodiments can make it possible to monitor an intensity impingement on the entire first facet mirror or on a predefined portion of the first facet mirror. For example, far field monitoring with good spatial resolution in respect of the captured portion of the first facet mirror can be provided via the measurement system by way of this.

In embodiments of a measurement method, the set of the measurement light individual beams is selected such that on the second facet mirror individual mirror groups are each impinged on by one of the measurement light individual beams, wherein at least one individual mirror which is not impinged on by measurement light which is guided to the detection device remains between two adjacent individual mirror groups respectively impinged on by the measurement light individual beams. Such embodiments make it is possible to avoid channel crosstalk between different measurement light individual beams during capturing via the detection device.

In embodiments of a measurement method, during the capturing or between successively performed capture steps, at least one individual mirror by which the captured measurement light beam is guided is tilted, wherein capturing is effected in a plurality of tilt positions of the individual mirror. Such embodiments make possible a calibration of the individual mirror tilted during capturing.

In embodiments of a measurement method, the set of the measurement light individual beams is selected or during measurement successive sets of measurement light individual beams are selected such that reflection properties of selected individual mirrors can be captured. Selecting the measurement light individual beams according to such embodiments can be sequentially logically combined so as to make it possible to deduce reflection properties of exactly one optical component or exactly one portion of a reflection surface of a selected optical component. For example, a spatially resolved reflection measurement of a reflection surface of a selected optical component of the illumination optical unit and/or of the imaging optical unit can be effected in this way.

In embodiments of a measurement method, the set of the measurement light individual beams is selected or during measurement successive sets of measurement light individual beams are selected such that reflection properties of selected mirrors of the imaging optical unit and/or of the illumination optical unit can be captured. A measurement method according to such embodiments makes it possible to determine spatially resolved reflection properties of at least one selected mirror and for example of a plurality of mirrors of the imaging optical unit of the measurement system. This imaging optical unit can be simultaneously usable as an imaging optical unit of the projection exposure apparatus for imaging a reticle onto a wafer. Alternatively or additionally, the measurement method can be effected for capturing reflection properties of selected mirrors of the illumination optical unit, which unit can simultaneously be used as an illumination optical unit of a projection exposure apparatus. Such an illumination optical unit can also include, besides the individual mirrors of the two facet mirrors, at least one further mirror or else a plurality of further mirrors which can be measured as an alternative or in addition to at least one mirror of the imaging optical unit with the aid of the measurement method.

In an aspect, the disclosure provides a projection exposure apparatus comprising a measurement system according to the disclosure. In an aspect, the disclosure provides a method of producing a structured component which comprises: carrying out the measurement method according to the disclosure; providing an object to be imaged in the form of a reticle; providing a wafer having a coating that is sensitive to the illumination light; projecting at least one portion of the reticle onto the wafer with the aid of the projection exposure apparatus according to the disclosure; and developing the light-sensitive layer exposed with the illumination light on the wafer. In aspect, the disclosure provides a component produced according to such a method. The features of such aspects can correspond to those which have been explained above with reference to the measurement system and the measurement method. The component produced can be a semiconductor element, for example a microchip, for example a memory chip.

### BRIEF DESCRIPTION OF THE DRAWINGS

At least one exemplary embodiment of the disclosure is described hereinafter with reference to the drawings, in which:

FIG. 1 schematically shows a meridional section of a projection exposure apparatus for EUV projection lithography;

FIG. 2 shows an embodiment of an optical system of a variant of the projection exposure apparatus including a measurement system comprising a measurement light beam selection device, by which at least one measurement light beam of illumination or measurement light guided in the optical system can be selected which is guided via two facet mirrors of an illumination optical unit of the optical system, and including a detection device for detecting the at least one selected measurement light beam, the detection device being arranged in the region of an image field;

FIG. 3 shows, in an illustration similar to FIG. 2, a further embodiment of the measurement system comprising a measurement light source arranged separately from a light source of the projection exposure apparatus for EUV projection used light;

FIG. 4 shows, once again in an illustration similar to FIG. 2, a further embodiment of the measurement system comprising a variant of the detection device arranged in the region of an object field of the projection exposure apparatus;

FIG. 5 shows, in an illustration similar to FIG. 4, one embodiment of the measurement system comprising a detection device in accordance with that according to FIG. 4 and a separate measurement light source in accordance with FIG. 3;

FIG. 6 shows, once again in an illustration similar to FIGS. 2 and 4, one embodiment of the measurement system comprising a detection device arranged in the region of a second facet mirror of the illumination optical unit of the projection exposure apparatus;

FIG. 7 shows, in an illustration similar to FIGS. 3 and 5, a variant of the measurement system comprising a detection device according to FIG. 6 and a separate measurement light source according to FIG. 2;

FIG. 8 shows a plan view of one example of a second facet of a second facet mirror of the illumination optical unit of the projection exposure apparatus, the illustration additionally also showing how a tilting of a first facet of the first facet mirror of the illumination optical unit influences a position of a point of incidence of a selected measurement light beam for two tilt angle degrees of freedom;

FIG. 9 shows an exemplary result of an intensity measurement by one of the detection devices according to FIGS. 2 to 6 upon carrying out a tilting in accordance with FIG. 8, illustrated for one exemplary tilt degree of freedom;

FIG. 10 shows one example of a channel assignment or of a selection of a set of measurement light individual beams between first facets or individual mirrors of the first facet mirror and second facets or individual mirrors of the second facet mirror of the illumination optical unit, illustrated by way of one example of a spatially resolved measurement result of a far field measurement by the detection device according to FIGS. 2 or 3;

FIG. 11 shows, in an illustration similar to FIG. 10, a further example of a channel assignment and a corresponding far field measurement result, for enabling a higher spatial resolution for measuring a portion illuminated with measurement light on the first facet mirror of the illumination optical unit;

FIG. 12 shows a plan view of the second facet mirror of the illumination optical unit of the projection exposure apparatus, with highlighting of two facets or individual mirrors of the second facet mirror that are used for one of the channel assignments for example according to FIGS. 10 or 11;

FIG. 13 shows, in an enlarged view, a detail of the second facet mirror, with highlighting of a grouping into individual mirror groups each having 2x2 groups for guiding a respective selected measurement light beam of the measurement system, the illustration showing overall an individual mirror unit composed of 23x23 individual mirrors;

FIG. 14 shows, in an illustration similar to FIG. 13, a further embodiment of an individual mirror unit, in this case comprising 11x11 individual mirrors and a corresponding 2x2 grouping as in FIG. 13;

FIG. 15 shows a measurement result of the detection device according to FIGS. 2 and 3 in the case of a channel assignment according to FIG. 13;

FIG. 16 shows an enlargement of a detail from FIG. 15, elucidating a resolution of the different measurement light individual beams selected by way of the measurement light beam selection device of the measurement system, namely by way of the chosen channel assignment;

FIG. 17 shows a more detailed plan view of the detection device according to FIGS. 4 and 5;

FIG. 18 shows a more detailed plan view of the detection device according to FIGS. 6 and 7;

FIG. 19 shows one example of an illumination setting resulting from corresponding channel assignment of the facet mirrors of the illumination optical unit in the form of an x-dipole setting, measured by way of the detection device according to FIG. 2;

FIGS. 20 and 21 schematically show two different channel assignments which can be measured by one of the detection devices according to FIGS. 2 to 6 and by way of which a comparison of reflectivities of selected facets or individual mirrors of the first and second facet mirrors of the illumination optical unit is possible; and

FIGS. 22 and 23 show two variants of guiding two exemplary selected measurement light beams within the measurement system according to FIGS. 2 or 3 for measuring a spatially resolved reflectivity of a reflection surface of a selected mirror of an imaging optical unit of the projection exposure apparatus.

### DETAILED DESCRIPTION

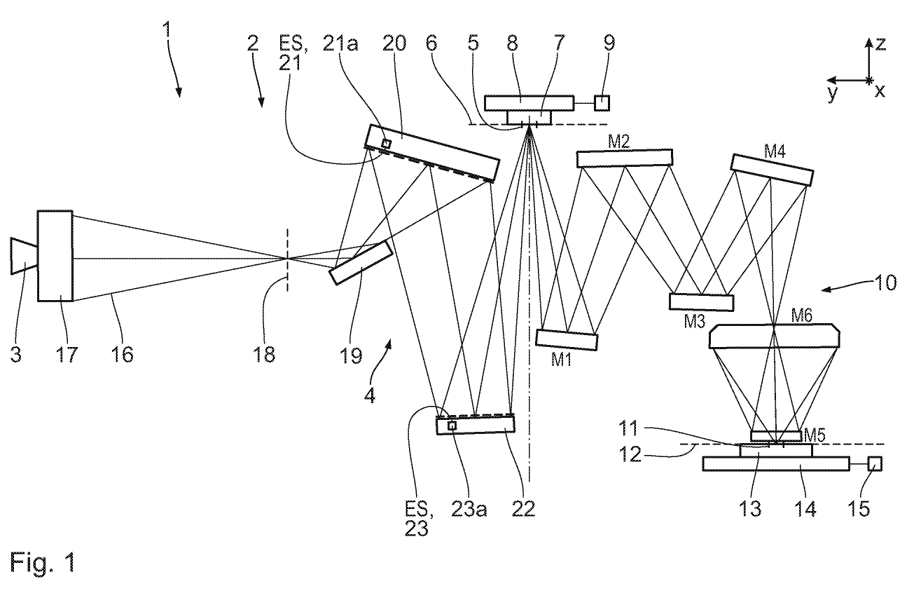

Certain constituent parts of a microlithographic projection exposure apparatus 1 are described in exemplary fashion below, initially with reference to FIG. 1. The description of the fundamental construction of the projection exposure apparatus 1 and the constituent parts thereof should be understood here to be non-limiting.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

For explanation purposes, a Cartesian xyz-coordinate system is depicted in FIG. 1. The x-direction runs perpendicularly to the plane of the drawing into the latter. The y-direction runs horizontally and the z-direction runs vertically. The scanning direction runs along the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example along the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits, for example, EUV radiation 16, which is also referred to below as used radiation, illumination radiation or illumination light. For example, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can constitute a separation between a radiation source module, comprising the radiation source 3 and the collector 17, and the illumination optical unit 4. The intermediate focus can have a diameter in the range of between 3 mm and 10 mm, for example in the range of 5 mm.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, the facet mirror is also referred to as a field facet mirror. The first facet mirror 20 comprises a multiplicity of individual first facets 21, which are also referred to below as field facets. FIG. 1 illustrates only some of the facets 21 by way of example.

The first facets 21 can be embodied as macroscopic facets, for example as rectangular facets or as facets with an arcuate edge contour or an edge contour of part of a circle. The first facets 21 can be embodied as plane facets or alternatively as convexly or concavely curved facets.

As known for example from DE 102008009600 A1, the first facets 21 themselves can also be composed in each case of a multiplicity of individual mirrors, for example a multiplicity of micromirrors. The first facet mirror 20 can be configured for example as a microelectromechanical system (MEMS system). For details, reference is made to DE 102008009600 A1.

Between the collector 17 and the deflection mirror 19, the illumination radiation 16 runs horizontally, i.e. along the y-direction.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1614008 B1, and US 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is likewise made to DE 102008009600 A1.

The second facets 23 can have plane reflection surfaces or, alternatively, convexly or concavely curved reflection surfaces.

The illumination optical unit 4 consequently forms a doubly faceted system. This fundamental principle is also referred to as a fly's eye condenser (fly's eye integrator).

It can be desirable to arrange the second facet mirror 22 not exactly in a plane that is optically conjugate to a pupil plane of the projection optical unit 10. For example, the pupil facet mirror 22 can be arranged so as to be tilted relative to a pupil plane of the projection optical unit 7, as is described, for example, in DE 102017220586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

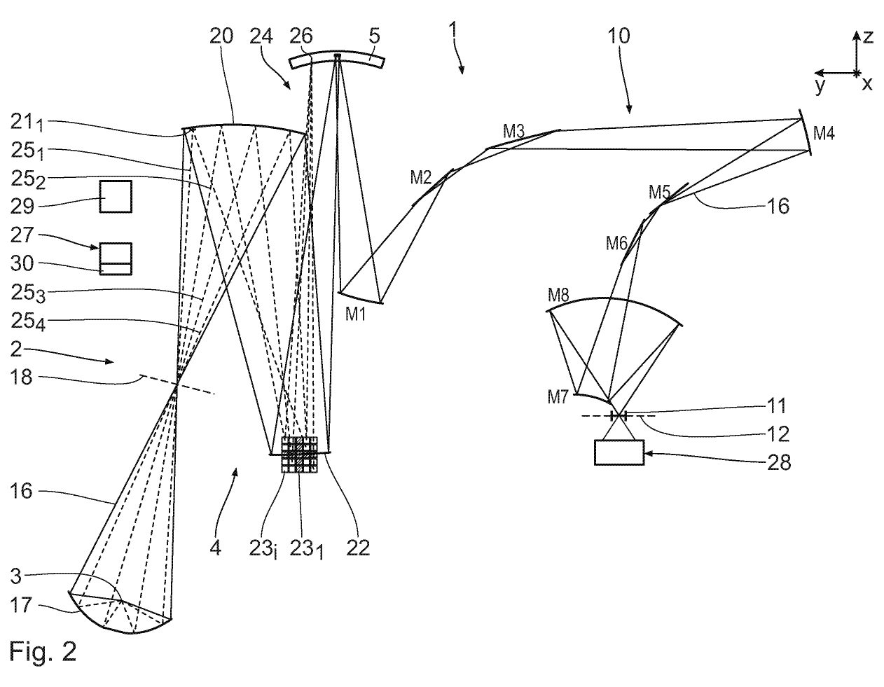

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22. Corresponding embodiments are also explained below, for example with reference to FIGS. 2 to 7.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image offset in the y-direction between a y-coordinate of a centre of the object field 5 and a y-coordinate of the centre of the image field 11. This object-image offset in the y-direction can be of approximately the same magnitude as a z-distance between the object plane 6 and the image plane 12.

For example, the projection optical unit 10 can have an anamorphic configuration. For example, it has different imaging scales βₓ, β_{y} in the x- and y-directions. The two imaging scales βₓ, β_{y} of the projection optical unit 10 can be at (βₓ, β_{y}) = (+/-0.25, +/-0.125). A positive imaging scale β means imaging without an image inversion. A negative sign for the imaging scale β means imaging with an image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x- and y-directions are known from US 2018/0074303 A1.

A further embodiment of the projection optical unit 10 is also explained below with reference to FIG. 2.

In each case one of the pupil facets 23 is assigned to exactly one of the field facets 21 for the purpose of forming a respective illumination channel for illuminating the object field 5. This can for example result in illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is for example as homogeneous as possible. It can have a uniformity error of less than 2%. Field uniformity can be attained by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, for example the subset of the pupil facets which guide light. This intensity distribution is also referred to as illumination setting or illumination pupil filling.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and for example of the entrance pupil of the projection optical unit 10 are described hereinafter.

The projection optical unit 10 can have a homocentric entrance pupil, for example. The latter can be accessible. It can also be inaccessible.

The entrance pupil of the projection optical unit 10 regularly cannot be exactly illuminated using the pupil facet mirror 22. In the case of imaging of the projection optical unit 10 which telecentrically images the centre of the pupil facet mirror 22 onto the wafer 13, the aperture rays often do not intersect at a single point. However, it is possible to find an area in which the distance of the aperture rays determined in pairs becomes minimal. This area represents the entrance pupil or an area in real space conjugate thereto. For example, this area exhibits a finite curvature.

It may be the case that the projection optical unit 10 has different positions of the entrance pupil for the tangential beam path and for the sagittal beam path. In this case, an imaging element, for example an optical component of the transfer optical unit, should be provided between the second facet mirror 22 and the reticle 7. With the aid of this optical element, the different position of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

FIG. 2 shows, once again in a meridional section, a further embodiment of the projection exposure apparatus 1, for example of an optical system that includes variants of the illumination system 2, of the illumination optical unit 4 and of the projection optical unit 10 of the projection exposure apparatus 1 according to FIG. 1. In addition, FIG. 2 shows one embodiment of a measurement system 24 for measuring optical properties of optical components of the illumination system 2 and/or of the projection optical unit 10. Components and functions corresponding to those which have already been explained above with reference to FIG. 1 bear the same reference signs, for example, and will not be discussed in detail again.

In the case of the illumination optical unit 4 of the projection exposure apparatus 1 according to FIG. 2, no deflection mirror is provided between the collector 17 and the first facet mirror 20. Some of the second facets 23 of the second facet mirror 22 are illustrated in an xy plan view in FIG. 2.

Between the light source 3 and the object field 5, which is likewise illustrated in an xy plan view in FIG. 2, the illumination system 2 according to FIG. 2 has exactly three components that reflect the illumination light 16, namely the collector 17, the first facets 21 of the first facet mirror 20 and the second facets 23 of the second facet mirror 22.

The projection optical unit 10 has a total of eight mirrors in the embodiment according to FIG. 2. Four of these mirrors, namely the mirrors M1, M4, M7 and M8, are embodied as NI (Normal Incidence) mirrors having an angle of incidence of the imaging light 16 of less than 45°. The other four mirrors M2, M3, M5 and M6 are embodied as GI (Grazing Incidence) mirrors for grazing incidence of the imaging light 16 with an angle of incidence of greater than 45°. Exclusively the last mirror M8 in the imaging light beam path, this mirror determining an image-side numerical aperture of the projection optical unit 10, has a passage opening for the imaging light 16. In contrast to the projection optical unit 10 according to FIG. 1, the penultimate mirror in the imaging beam path in the case of the projection optical unit 10 according to FIG. 2 does not have a passage opening for the imaging light 16. A projection optical unit corresponding to the projection optical unit 10 according to FIG. 2 is known from US 10,146,033 B2.

The measurement system 24 according to FIG. 2 uses the EUV used light source 3 of the projection exposure apparatus 1 as measurement light source and uses selected first facets or individual mirrors of the first facet mirror 20 and second facets 23 or individual mirrors of the second facet mirror 22 for beam guidance of the illumination light 16, then serving as measurement light. Some selected measurement light individual beams 25ᵢ are highlighted using dashed lines in FIG. 2.

The measurement light individual beam 25₁ is predefined in terms of its course by way of tilt positions of at least one selected individual mirror or a field facet 21₁ of the first facet mirror 20 and at least one individual mirror or a second facet 23₁ of the second facet mirror 22. The second facet 23₁ is tilted such that the measurement light individual beam 25₁ is incident on a selected measurement field point 26 arranged in the object field 5. A reflective micromirror of the measurement system 24 is arranged at the location of the measurement field point 26. A pinhole that allows the corresponding measurement light individual beam 25ᵢ to pass through the object plane 6 can also be provided instead of such a reflective micromirror.

A combination of such a pinhole in the object plane 6 with at least one mirror is also possible for guiding the respective measurement light individual beam 25ᵢ.

A corresponding reflective micromirror or a corresponding pinhole configuration can also be provided in the image plane 12, in a manner comparable with the measurement principle known from DE 102018207384 B4.

The object field 5 is shaped as part of a ring in the embodiment according to FIG. 2.

Via the projection optical unit 10, the measurement light individual beam 25₁ is then guided towards the image field 11 and transferred to a measurement image field point, not specifically illustrated in FIG. 2.

The other measurement light individual beams 25ᵢ (i=2,...) are also transferred to the measurement field point 26 via corresponding pairings of the first facets/individual mirrors 21ᵢ and the second facets/individual mirrors 23ᵢ and are correspondingly imaged into the measurement image point via the projection optical unit 10.

Situated in the region of the measurement image point in the image plane 12 there is a pinhole of the measurement system 24, which blocks other light that impinges on the image plane 12 outside the measurement image point.

A corresponding sensor arrangement is known from DE 102018207384 B4.

During operation of the measurement system 24, the two facet mirrors 20, 22 serve for selecting at least one measurement light beam of the illumination light, namely the at least one measurement light individual beam 25ᵢ.

The measurement system 24 furthermore includes a detection device 28 for detecting the measurement light individual beams 25ᵢ. The detection device 28 is disposed downstream of the image plane 12 in the imaging light beam path of the projection optical unit 10. Insofar as the detection device 28 is measurement-active, the wafer holder 14 and the wafer 13 are situated outside the imaging light beam path of the projection optical unit 10. The detection device 28 is embodied in spatially resolving fashion. The detection device 28 has a sensor array arranged parallel to the xy-plane. This sensor array can be a CMOS array or a CCD array. A number of sensor pixels of the sensor array of the detection device 28 is at least equal to a maximum number of measurement light individual beams 25ᵢ predefinable via the measurement light beam selection device of the measurement system 24. The sensor array can have for example 10⁶, 10⁷ or even 10⁸ sensor pixels, for example an array comprising 10000 x 10 000 sensor pixels.

The detection device 28 can be embodied or arranged such that an intensity distribution of the measurement light individual beams 25ᵢ in a pupil plane of the projection optical unit 10 can be measured by the sensor array of the detection device 28.

The detection device 28 can be embodied as a pinhole camera.

Alternatively or additionally, the detection device 28 can also be embodied such that it measures an intensity distribution of the measurement light 25 in the image plane 12.

A measurement light beam selection device 27 illustrated schematically in FIG. 2 serves for controlling the first facets/individual mirrors 21ᵢ and the second facets/individual mirrors 23ᵢ for predefining the measurement light individual beams 25ᵢ. The measurement light beam selection device 27 is signal-connected to tilting or translation actuators 21a/23a (cf. FIG. 1) of the individual mirrors/first facets 21ᵢ of the first facet mirror 20 and of the individual mirrors/second facets 23ᵢ of the second facet mirror 22 for the purpose of controlling a respective position/tilt position.

Each of the second facets 23ᵢ of the second facet mirror 22 is subdivided into a 2x2 array of assigned individual mirrors. In FIG. 2, the four individual mirrors of the second facet mirror 22 that form a respective second facet 23ᵢ are depicted as blank. These in total four 2x2 facets 23ᵢ of the second facet mirror 22 are separated by a row or a column of individual mirrors of the second facet mirror 22 that are not used for guiding measurement light individual beams 25ᵢ. In FIG. 2, these non-used individual mirrors are depicted as filled in.

The separation of the second facets 23ᵢ by way of corresponding rows/columns of individual mirrors of the second facet mirror 22 that are not used for guiding the measurement light 25 avoids overexposure of the second facets 23ᵢ and thus channel crosstalk during the simultaneous measurement of a plurality of measurement light individual beams 25ᵢ guided adjacently in the region of the second facet mirror 22 via the sensor array of the detection device 28.

The measurement system 24 furthermore includes a control/regulating device 29, which is signal-connected to the tilting actuators 21a, 23a of the facets/individual mirrors 21, 23 of the two facet mirrors 20, 22, to the measurement light beam selection device 27 and to the detection device 28. The control/regulating device 29 can be embodied such that it processes a measurement program for measuring selected illumination and/or imaging parameters of the projection exposure apparatus 1. By way of the control/regulating device 29, for example the projection exposure apparatus 1 can be switched between a used mode of operation, during which the wafer holder 14 and the wafer 13 are present in a used position according to FIG. 1, and a measurement mode of operation in accordance with FIG. 2.

By way of the measurement light beam selection device 27, a plurality of measurement light beams of the illumination light 16, namely the plurality of measurement light individual beams 25ᵢ, can be selected simultaneously and this plurality of measurement light individual beams 25ᵢ can be measured simultaneously via the detection device 28. The number of simultaneously measurable measurement light individual beams 25ᵢ can be greater than 10, can be greater than 100 and can also be greater than 1000. This number is dependent on the number of mutually independently predefinable measurement light individual beams 25ᵢ and on the resolution capability of the sensor array of the detection device 28.

In the measurement mode of operation, a reflective object corresponding to the reticle 7 can be used, in principle, which reflects the illumination light 16 incident on the object field 5 from the illumination light beam path of the illumination optical unit 4 into the imaging light beam path of the projection optical unit 10. Alternatively, the abovementioned at least one reflective micromirror at the location of the measurement field point 26 can be part of the illumination selection device 27. In this case, a corresponding micromirror arrangement is established instead of the reticle 7 in the measurement mode of operation.

Part of the measurement light beam selection device 27 is an individual mirror selection device 30, which is signal-connected to the control/regulating device 29. Individual mirrors/facets 21ᵢ, 23ᵢ of the first facet mirror 20 and of the second facet mirror 22, respectively, by which a respective measurement light beam, i.e. a respective measurement light individual beam 25ᵢ, is guided can be selected by the individual mirror selection device 30. Using the individual mirror selection device 30, for example, for the analysis of an illumination light far field in which the first facet mirror 20 is arranged, it is possible to select individual mirror support points within the first facet mirror 20, namely to select corresponding individual mirrors/facets 21ᵢ of the first facet mirror 20 that guide measurement light individual beams 25ᵢ, in order to cover this far field in a predefined manner for the analysis of an intensity distribution of the illumination light 16 over the far field.

The individual mirror selection device 30 is additionally embodied as an individual mirror group selection device which enables selection of groups of individual mirrors 21ᵢ, 23ᵢ of the first facet mirror 20 and/or of the second facet mirror 22 by which the respective measurement light beam, i.e. the respective measurement light individual beam 25ᵢ, is guided. Such a selection is illustrated in FIG. 2, where the individual mirror selection device 30 has predefined a corresponding 2x2 array arrangement of the individual mirrors of the second facet mirror 22. By way of the individual mirror selection device 30 embodied as an individual mirror group selection device, groups of the individual mirrors 23ᵢ of the second facet mirror 22 can be selected in order to optimize a spatial resolution of an imaging for example of individual mirrors 21ᵢ of the first facet mirror 20 that are grouped into first facets.

The measurement system 24 also makes it possible to calibrate tilt angles of the individual mirrors/facets 21ᵢ, 23ᵢ of the two facet mirrors 20, 22, as will also be explained below.

Parameters of the light source 3, for example a temporal stability of location and/or power of the light source 3, can be measured by the measurement system 24.

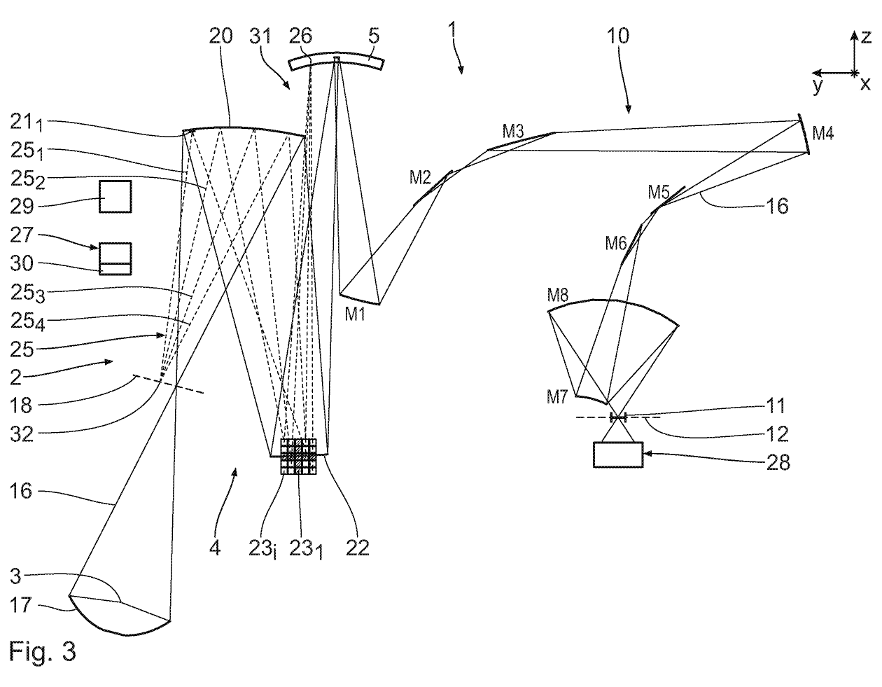

FIG. 3 shows a variant of a measurement system 31, which can be used as an alternative or in addition to the measurement system 24 according to FIG. 2. Components and functions corresponding to those which have already been explained above with reference to FIGS. 1 and 2 bear the same reference signs and will not be discussed in detail again.

The measurement system 31 has a dedicated measurement light source 32 separately from the light source 3 for the EUV used radiation 16 of the projection exposure apparatus 1. A wavelength of measurement light 25 of the measurement light source 32 can correspond to that of the light source 3 for the used illumination light of the projection exposure apparatus 1. Alternatively, the wavelength of the measurement light 25 can also differ from that of the illumination or imaging light 16 of the projection exposure apparatus 1. The wavelength can be in the visible spectral range, for example. The latter affords a large selection of different light sources which can be selected depending on the given desired specific wavelength or specific wavelength range, with regard to a source variable, with regard to a source intensity, with regard to controllability for example for generating a pulsed or clocked light source and/or with regard to a possibility of an array arrangement. Such measurement light sources in the visible spectral range also enable measurement of mirrors or micromirrors designed for EUV used illumination light.

Insofar as layer properties of the mirrors to be measured are intended to be checked, for example, the wavelength of the measurement light 25 can correspond to that of the used illumination light of the projection exposure apparatus 1.

The measurement light source 32 itself or a measurement light focus of the measurement light source 32 lies adjacent to the intermediate focus of the illumination light 16 in the intermediate focal plane 18. A distance between both foci can be less than 10 mm and can be for example less than 5 mm. The distance between the two foci, for example in a dimension that lies in the intermediate focal plane 18, can also be greater than 10 mm and can be in the range of between 20 mm and 50 mm. In a dimension perpendicular to the intermediate focal plane 18, this distance can also be even greater and can be in the range of between 10 mm and 150 mm, for example.

A plurality of such measurement light sources 32 surrounding the intermediate focus of the illumination light 16 in the region of the intermediate focal plane 18 are also possible, such that desired tilt angle amplitudes of the mirrors on the first facet mirror 20 remain manageably low depending on the selection of the measurement light source. This plurality of measurement light sources can surround the intermediate focus in the intermediate focal plane 18 on a plurality of sides.

A power and also an emission characteristic of the measurement light source 32 are stable within narrow tolerance limits. The power can fluctuate by less than 1%, by less than 0.1%, or even by less than 0.01%, within a time period of one hour, for example. There is typically a fluctuation bandwidth for values which are greater than 1x10⁻⁵.

Similar or identical tolerance limits apply to typical parameters of the emission characteristic, i.e. to a directional stability and to a divergence stability of the measurement light source 32.

By way of the measurement light beam selection device 27, tilt angles of the individual mirrors/facets 21ᵢ, 23ᵢ are predefined such that, via the measurement system 31, the measurement light individual beams 25₁ to 25₄are guided via selected ones of the individual mirrors/first facets 21ᵢ of the first facet mirror 20 and selected ones of the individual mirrors/second facets 23ᵢ of the second facet mirror 22 once again to the measurement field point 26. If the intention is to use pairings of the individual mirrors/facets 21ᵢ, 23ᵢ for guiding the measurement light individual beams 25ᵢ which are the same as the pairings used for the beam guiding according to FIG. 2, the spatial deviation between the measurement light source 32 and the intermediate focus of the light source 3 in the intermediate focal plane 18 results in a different set of tilt angles of the individual mirrors/first facets 21ᵢ in the case of the measurement system 31 in comparison with the measurement system 24.

Using the detection device 28 of the measurement system 31, the measurement light individual beams 25ᵢ are then detected, in this case proceeding from the measurement light source 32. A wavelength sensitivity of the sensor array of the detection device 28 is correspondingly adapted to the wavelength of the measurement light of the measurement light source 32.

The measurement systems 24 and 31 additionally make it possible to monitor properties of the projection optical unit 10, for example an alignment and/or reflection properties of the mirrors Mᵢ.

In an embodiment of the measurement system that is not illustrated, the measurement light source 32 and the detection device 28 are present in an interchanged arrangement, such that a measurement light beam path proceeding from the image field 11 towards the intermediate focal plane 18 is traversed by the measurement light 25 and the measurement light individual beams 25ᵢ exactly in the opposite direction, as explained above with reference to FIG. 3. A measurement result complementary to the possible measurement result of the measurement system 31 is achievable with such an interchanged arrangement of the measurement light source with the detection device.

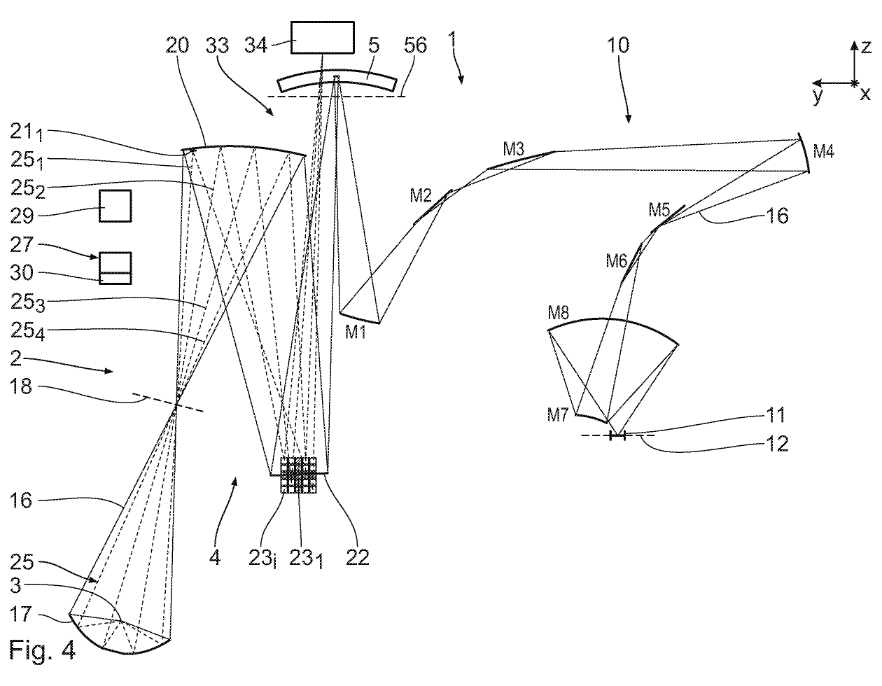

With reference to FIG. 4, an explanation is given below of a further embodiment of a measurement system 33, which can be used as an alternative or in addition to the measurement systems described above. Components and functions corresponding to those which have already been explained above with reference to FIGS. 1 to 3 bear the same reference signs and will not be discussed in detail again.

In the case of the measurement system 33, the measurement light individual beams 25ᵢ are not reflected in the object field, but rather guided towards a detection device 34 of the measurement system 33, which captures a distribution of the measurement light in the beam path of the measurement light 25 alongside the object field 5. The detection device 34 is at a distance from the object plane 6 in the z-plane. In actual fact, in contrast to what is indicated in the schematic illustration according to FIG. 4, the detection device 34 is regularly not arranged above the object field 5, but rather displaced for example at a distance in the range of between 10 mm and 100 mm below the object field 5, i.e. in the negative z-direction in FIG. 4. At least one additional mirror, not illustrated in FIG. 4, can then also be used for guiding the respective measurement light individual beam 25ᵢ. In the case of the measurement system 33, the detection device 34 is arranged in the region of the object field 5.

In this case, the measurement light 25 can pass through the object plane 6 outside or else within the object field 5. Depending on that, in the measurement mode of operation of the measurement system 33, the reticle 7 can possibly remain in situ or is to be removed from the beam path of the measurement light.

The embodiment of the detection device 34 corresponds, apart from the arrangement in the region of the object plane 6, to the embodiment of the detection device 28.

The detection device 34 can in turn be arranged such that a measurement light angle distribution with which the measurement light is incident on the object plane 6 and/or a measurement light intensity distribution is measured. In the region of the object plane 6, the measurement system 33 can in turn have a pinhole for the passage of the measurement light 25.

Tilt angles of the individual mirrors/facets of the facet mirrors 20, 22 can be calibrated with the aid of the measurement system 33. This tilt angle calibration can be effected for example during a used mode of operation of the projection exposure apparatus 1 in the case of individual mirrors/facets 21ᵢ, 23ᵢ that are not used for guiding the used illumination light 16 during this used mode of operation. A measurement mode of operation and a production mode of operation can thus take place in parallel during use of the measurement system 33.

Far field monitoring is also possible using the detection device 34 of the measurement system 33, in line with what has been explained above for example in connection with the measurement system 24 according to FIG. 2.

In the case of the measurement system 33, the light source 3 for the used illumination light 16 simultaneously generates the measurement light 25 as well, in line with what has been explained in connection with the measurement system 24 according to FIG. 2.

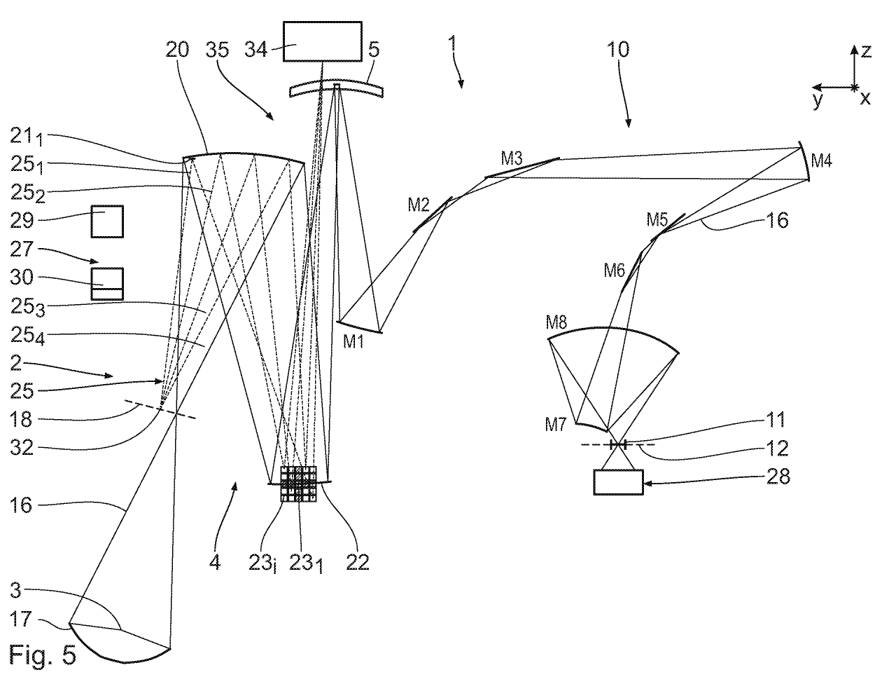

FIG. 5 shows a further measurement system 35, which can be used as an alternative or in addition to the measurement systems explained above. Components and functions corresponding to those which have already been explained above with reference to FIGS. 1 to 4 bear the same reference signs and will not be discussed in detail again.

In line with the measurement system 31 according to FIG. 3, the measurement system 35 has a measurement light source 32 for the measurement light 25, the measurement light source being separate from the light source 3. In the region of the object plane 6, the measurement system 35 is embodied like the measurement system 33 according to FIG. 4.

Using the measurement system 35 according to FIG. 5, individual mirrors/facets of the two facet mirrors 20, 22 that are used during a used mode of operation can also be measured in a measurement mode of operation in parallel therewith, such that for example a calibration of tilt angles of the individual mirrors/facets of the two facet mirrors 20, 22 is possible during the used mode of operation.

Measurement possibilities of the measurement system 35 correspond to those of the measurement system 33, apart from the fact that there is no monitoring of light source parameters of the light source 3.

In the case of the measurement system 35, too, it is possible to interchange the measurement light source 32 with the detection device 34 for measuring a measurement light beam path running in the opposite direction in comparison with the used light beam path, as already discussed above in connection with FIG. 3.

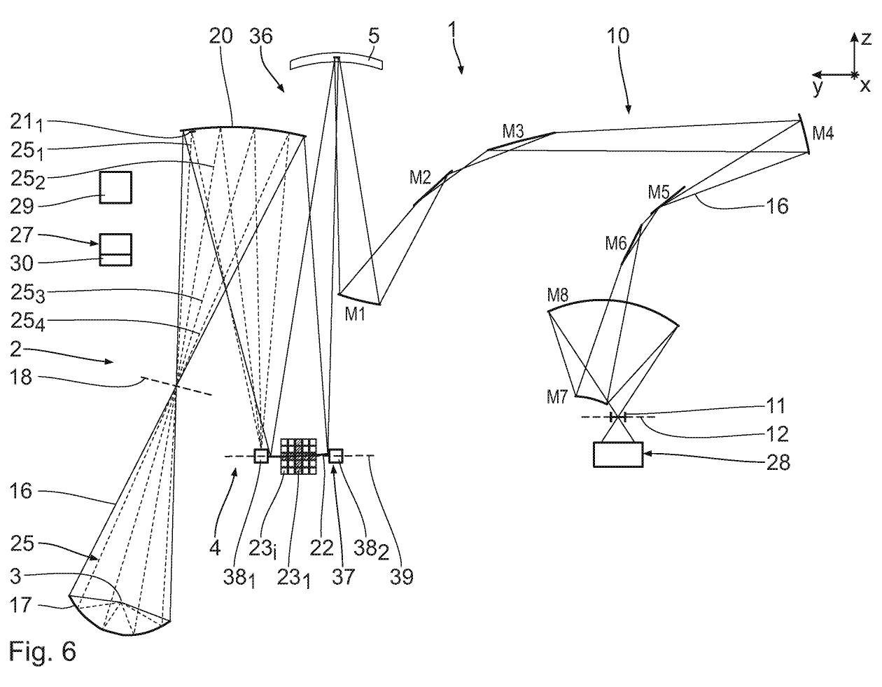

FIG. 6 shows a further embodiment of a measurement system 36, which can be used as an alternative or in addition to one of the measurement systems described above in the case of the projection exposure apparatus 1. Components and functions corresponding to those which have already been explained above with reference to FIGS. 1 to 5 bear the same reference signs and will not be discussed in detail again.

The measurement system 36 has a detection device 37 in the region of an arrangement plane of the second facet mirror 22. FIG. 6 illustrates two detectors 38₁, 38₂ arranged on the left and right of the second facet mirror 22 in FIG. 6.

In addition, further detectors 38₃, 38₄ of the detection device 37 can also be arranged perpendicular to the plane of the drawing in FIG. 6, in front of and behind the second facet mirror 22.

Each of the detectors 38ᵢ has a sensor array in line with what has been explained above in connection with the detection devices 28 and 34.

The detectors 38ᵢ can in turn be embodied as pinhole cameras, i.e. can measure an angle distribution of the measurement light individual beams 25ᵢ in the arrangement plane 39 of the second facet mirror 22, or can also be embodied as sensor arrays arranged directly in the arrangement plane 39 for measuring an intensity distribution of the measurement light 25 in the arrangement plane 39.

Tilt angles of individual mirrors/first facets 21ᵢ that are used for guiding the measurement light individual beams 25ᵢ are predefined by way of the measurement light beam selection device 27 and the individual mirror selection device 30 such that a respective one of the detectors 38ᵢ of the detection device 37 is impinged on by the respective measurement light individual beam 25ᵢ. FIG. 6 shows a guiding variant for the measurement light individual beams 25ᵢ which involves all the measurement light individual beams 25ᵢ shown being directed onto the detector 38₁. A distribution among the different detectors 38ᵢ is also possible by appropriate selection of the individual mirrors/first facets 21ᵢ and the tilt angles thereof.

A calibration of tilt angles of the individual mirrors/first facets 21ᵢ of the field facet mirror 20 can be carried out via the detection device 37 arranged in the region of the second facet mirror 22. In principle, this can be done in a measurement mode of operation in parallel with the used mode of operation in line with what has been explained above in connection with the measurement system 33 according to FIG. 4.

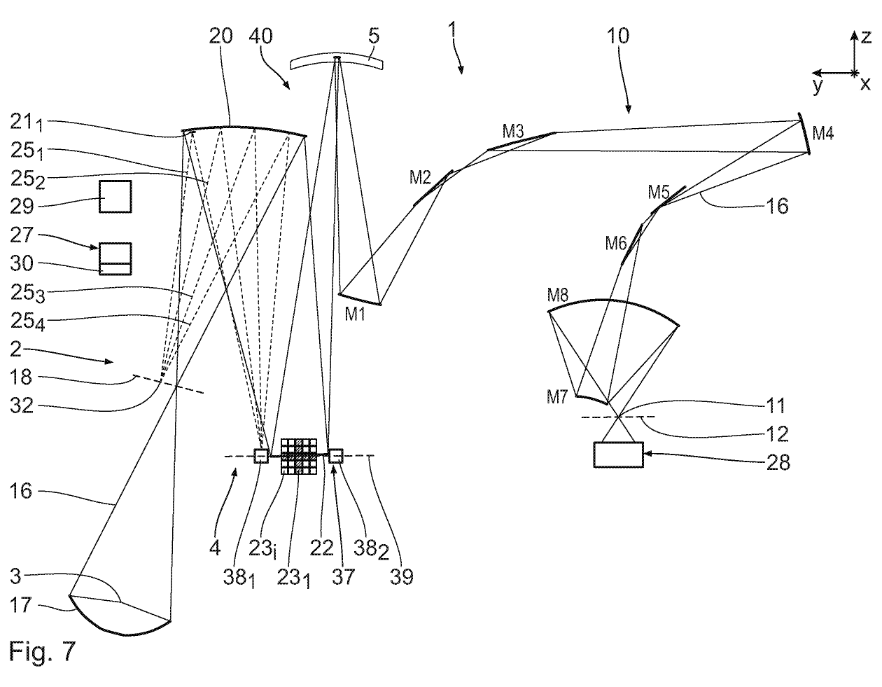

FIG. 7 shows a further embodiment of a measurement system 40, which can be used as an alternative or in addition to one of the measurement systems described above. Components and functions corresponding to those which have already been explained above with reference to FIGS. 1 to 6 bear the same reference signs and will not be discussed in detail again.

The measurement system 40 has a detection device 37 comprising detectors 38ᵢ in accordance with the measurement system 36 and additionally has a measurement light source 32 independent of the light source 3 for the used illumination light 16, like the measurement systems according to FIGS. 3 and 5.

An alternative arrangement to the measurement system 40 is possible, too, in which the measurement light source 32 and the detection device 37 are arranged in an interchanged manner.

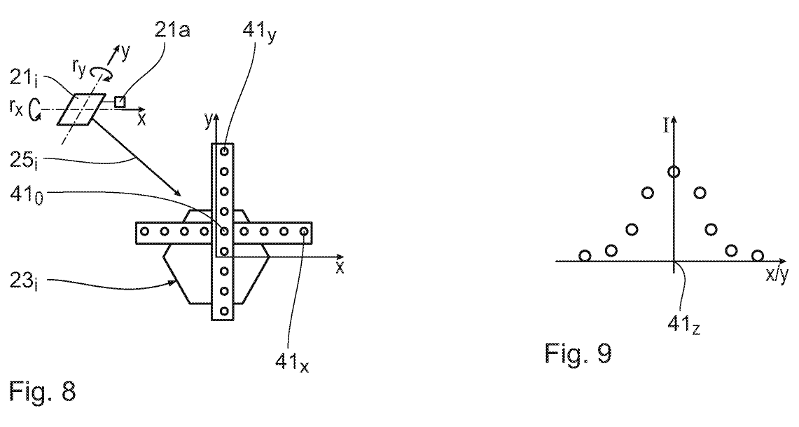

FIGS. 8 and 9 elucidate a measurement method which is able to be carried out by one of the measurement systems according to FIGS. 2 to 5. This measurement method according to FIGS. 8 and 9 uses the measurement system to have a detection device in the beam path of the measurement light 25 after reflection at the individual mirrors/second facets 23ᵢ of the field facet mirror 22. This is the case for the measurement systems 24, 31, 33 and 35 according to FIGS. 2 to 5.

FIG. 8 shows one of the second facets 23ᵢ, embodied in this case as a monolithic facet having a hexagonal boundary.

The illustration furthermore shows an initial spot position 41₀ of a point of incidence of one of the measurement light individual beams 25ᵢ on this second facet 23ᵢ. This measurement light individual beam 25ᵢ is reflected to the second facet 23ᵢ by way of an individual mirror or a first facet 21ᵢ, which can be tilted by way of a corresponding actuator 21a firstly by a tilt angle rₓ about a tilt axis parallel to the x-axis and secondly by a tilt angle r_{y} about a tilt axis parallel to the y-axis.

A tilt by rₓ leads to a displacement of the spot position along the y-coordinate in the arrangement plane of the second facet 23ᵢ, as is indicated in FIG. 8 by spot positions 41_{y} within a displacement path extending along the y-coordinate. A tilt of the individual mirror or the first facet 21ᵢ by r_{y} correspondingly leads to a displacement of the spot position 41 along the x-coordinate into a displaced spot position 41ₓ, as is indicated in turn in FIG. 8 within a corresponding displacement path extending along the x-coordinate. In the total displacement field around the initial spot position 41₀ in the x- and y-directions, the field being possible by way of a total tilt of the individual mirror/the first facet 21ᵢ by rₓ, r_{y‘}, the point of incidence of the measurement light individual beam 25ᵢ leaves the reflection surface having a hexagonal boundary of the second facet 23ᵢ towards both sides of the second facet 22ᵢ.

FIG. 9 shows the result of a measurement light intensity measurement of the measurement light 25 guided along the measurement light individual beam 25ᵢ with the aid of the respective detection device 28 or 34. The illustration shows a measurement intensity I as a function of the respective displacement coordinate of the spot position 41 in the x- or y-direction. On account of the measurement light individual beam being cut off at the edges of the second facet 23ᵢ, the measurement intensity I falls to 0 depending on x/y displacement, i.e. depending on rₓ/r_{y} tilt angles of the individual mirror/the first facet 25ᵢ proceeding from a central spot position 41_{z}, at which the maximum measurement light intensity is measured, in the +/− direction of the respective coordinate x/y. The measurement light intensity is 0 when the measurement light individual beam 25ᵢ completely misses the second facet 23ᵢ.

That tilt position r_{xz}, r_{yz} for which the spot position 41_{z} lies centrally on the second facet 23ᵢ can be deduced from the x/y-coordinate-dependent measurement light intensity result I according to FIG. 9. The associated actuator control of the tilting actuator 21ₐ can then be stored in a calibration table in the context of the measurement method. For this purpose, the control/regulating device 29 can have a corresponding data memory.

In the case where the measurement systems 31, 35 are used with interchanged positions of the measurement light source 32 and the respective detection device 28 or 34, a corresponding intensity distribution can also be ascertained for the individual mirrors/second facets 23ᵢ of the second facet mirror 22. Accordingly, a calibration of the tilting actuators 23a of the second facet mirror 22 is possible by this approach.

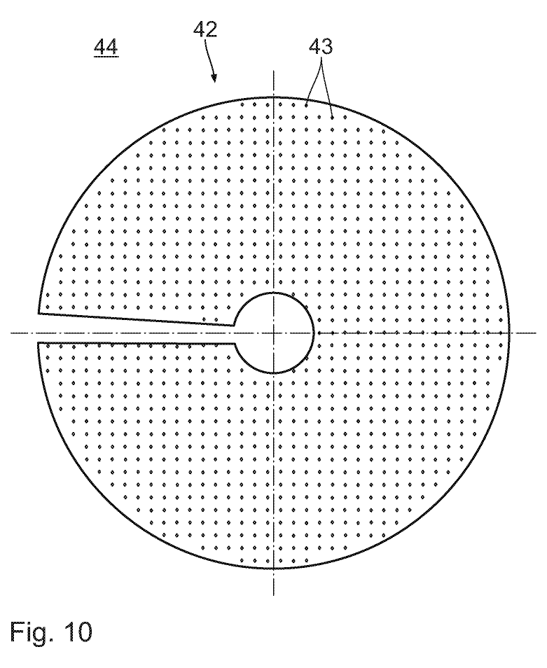

FIG. 10 shows a spatially resolved measurement result of the sensor arrays of the detection devices 28 and respectively 34 of the measurement systems 24, 31, 33, 35 according to FIGS. 2 to 5 for a given assignment of the individual mirrors/facets 21, 23 to measurement light individual beams 25ᵢ, predefined by way of the individual mirror selection device 30 of the respective measurement system.

In the case of the measurement according to FIG. 10, this individual mirror/facet assignment is such that on the first facet mirror 20 a regular x/y grid of the individual mirrors/first facets 21 on the first facet mirror 20 is illuminated by corresponding measurement light individual beams 25ᵢ and fed to the detection devices 28 and respectively 34 by way of assigned second facets 23ᵢ. Assuming a corresponding assignment, an intensity distribution 42 corresponding to the grid arrangement of the individual mirrors/first facets 21ᵢ on which the measurement light individual beams 25ᵢ impinge given the assignment arises on the sensor arrays of the detection devices 28 and respectively 34. Each spot 43 of the intensity distribution 42 has an intensity which is a measure of the intensity of the respective measurement light individual beam 25ᵢ.

Assuming a previously known reflectivity of the individual mirrors/first facets 21ᵢ of the first facet mirror 20 and of the second facets 23ᵢ of the second facet mirror, the intensity distribution 42 according to FIG. 10 is a measure of an intensity distribution of a far field 44 of the light source 3 of the projection exposure apparatus 1, the first facet mirror 20 being arranged in this far field. This holds true, of course, only if the illumination light source 3 is used as measurement light source, i.e. when the measurement system 24 or 33 is used. When the measurement systems 31 or 35 are used, the intensity distribution 42 can again offer a conclusion about reflectivities of the individual mirrors/facets 21ᵢ, 23ᵢ on which the respective measurement light individual beams 25ᵢ impinge.

Using the measurement systems 24 or 33, an intensity distribution of the far field 44 can thus be measured by way of an intensity distribution according to FIG. 10. Reflectivity products of the individual mirrors/facets 21ᵢ, 23ᵢ that guide the measurement light individual beams 25ᵢ can be measured by the measurement systems 31 or 35.

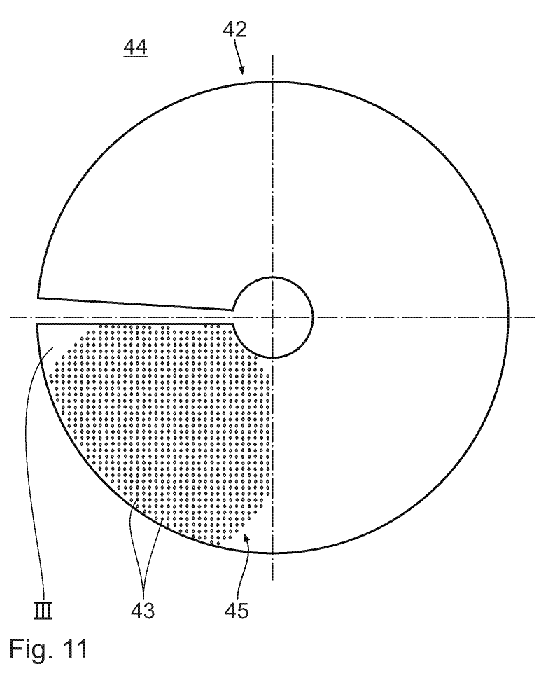

FIG. 11 shows a variant of a channel assignment of the individual mirrors/facets 21ᵢ of the first facet mirror 20 to the second facets 23ᵢ of the second facet mirror 22, once again set by way of the individual mirror selection device 30 of the respective measurement system. The assignment according to FIG. 11 is such that only a portion of the first facet mirror 20, for example the quadrant III thereof, is impinged on by the respective measurement light individual beams 25ᵢ. Assuming that the number of measurement light individual beams 25ᵢ is the same as in the case of the intensity distribution 42 according to FIG. 10, an intensity distribution 45 which is denser than the intensity distribution 42 according to FIG. 10 by a factor of 4 results for the assignment according to FIG. 11. For example, an intensity distribution of the far field 44 with higher spatial resolution can thus be measured by way of the intensity distribution 45 according to FIG. 11.

Alternatively, as explained above in association with FIG. 10, in the case of the channel assignment according to FIG. 11 it is possible to carry out a reflectivity measurement of the individual mirrors 21ᵢ of the first facet mirror 20 in the quadrant III with higher density, such that a larger number of the individual mirrors 21ᵢ of the first facet mirror 20 can be measured in this quadrant.

Far field disturbances with a higher spatial frequency and/or single individual mirrors or single facets 21ᵢ, 23ᵢ of the facet mirrors 20, 22 with a reflectivity beyond predefined limit values can thus be captured.

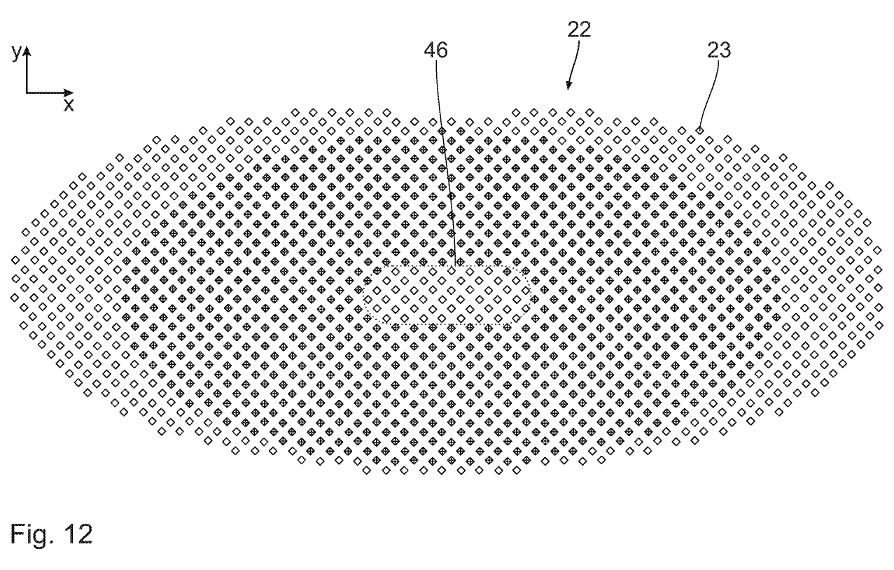

FIG. 12 shows a plan view of the second facet mirror 22 in the case of an embodiment of the illumination optical unit 4 as a specular reflector. This embodiment of the second facet mirror 22 as a pupil facet mirror is embodied for arrangement in an arrangement plane which is at a distance from a pupil plane of the illumination optical unit 4 of the projection exposure apparatus 1. An outer edge contour of a close-packed arrangement of the second facets 23 of the second facet mirror 22 has an approximately kidney- or bean-shaped design with an x/y aspect ratio in the range of between 1.5 and 5.

In FIG. 12, in a central region, having an elliptic boundary, of the second facet mirror 22 with an inner, approximately stadium-shaped obscuration cutout 46, those second facets 23 which are used in the case of the assignment of the individual mirrors/facet mirrors 21ᵢ, 23ᵢ for guiding the measurement light individual beams 25ᵢ according to FIGS. 10 and 11 are highlighted by a “+” symbol. The second facets 23 according to FIG. 12 can be virtual second facets attained by grouping of a plurality of micromirrors, or else monolithic second facets.

Images of a source volume of the light source 3 arise on the second facets 23. The second facets 23 additionally have the task of imaging the first facets or individual mirrors 21 of the first facet mirror 20 into the object plane 6.

The number of individual mirrors/second facets 23ᵢ used here for guiding the measurement light individual beams 25ᵢ is significantly smaller than a total number of the individual mirrors/second facets 23ᵢ of the second facet mirror 22 and can be in the range of between 30% and 80%, for example. Smaller or larger ratio values are also possible. In the case of a measurement carried out by one of the measurement systems explained above, it is also possible to use significantly fewer individual mirrors/facets 21ᵢ, 23ᵢ for guiding the measurement light individual beams 25ᵢ, i.e. it is possible to employ significantly fewer measurement light individual beams 25ᵢ for measurement, for example only some of the measurement light individual beams 25ᵢ, e.g. in the range of between two and 100 measurement light individual beams 25ᵢ.

Several hundred measurement light individual beams 25ᵢ are used in the case of the assignment according to FIG. 12. More than a thousand measurement light individual beams 25ᵢ can also be used and processed in parallel by one of the measurement systems explained above and measured via the respective detection devices.

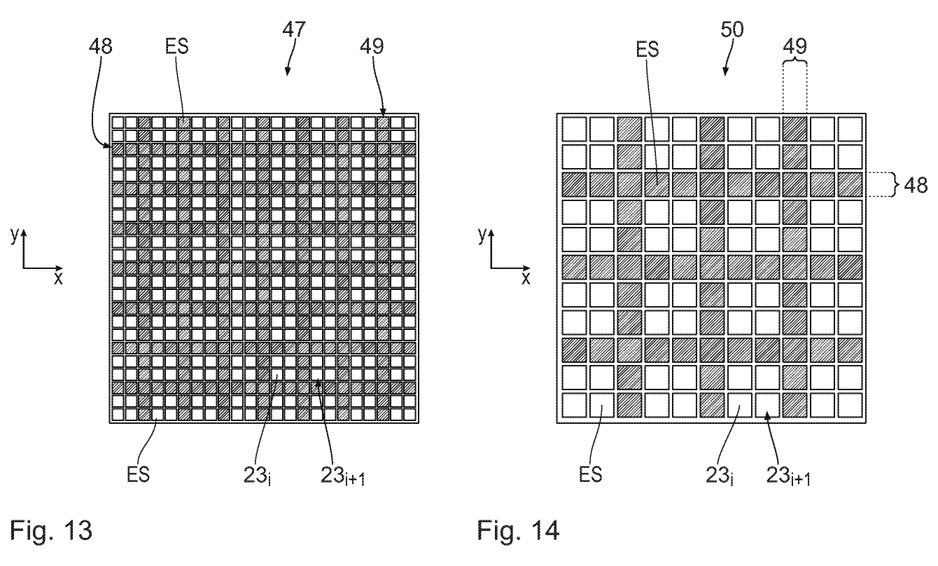

FIG. 13 shows in detail a section of the second facet mirror 22, namely an individual mirror unit 47, from which a MEMS variant of the second facet mirror 22 is constructed.

The MEMS unit 47 is subdivided into 23x23 individual mirrors ES.

FIG. 13 additionally illustrates an assignment of the individual mirrors ES to measurement light individual beams 25ᵢ for a measurement which can be carried out by one of the measurement systems explained above. Individual mirrors ES impinged on by a respective measurement light individual beam 25ᵢ are depicted as blank and the individual mirrors of the individual mirror unit 47 that are not impinged on by used measurement light 25 are depicted as filled in.

The individual mirrors ES impinged on by the used measurement light 25 are subdivided into 2x2 individual mirror groups, each of these individual mirror groups forming a second facet 23ᵢ of the second facet mirror 22. Each of the second facets 23ᵢ guides exactly one measurement light individual beam 25ᵢ. Alternatively, the individual mirrors ES of one of the 2x2 individual mirror groups can also guide a plurality of measurement light individual beams 25ᵢ. These second facets 23ᵢ are arranged in an xy grid in a manner distributed uniformly over the individual mirror unit 47 such that a row 48 or a column 49 of individual mirrors ES that are not impinged on by used measurement light 25 is in each case present between two adjacent ones of the second facets 23ᵢ.

In the case of the illustrated assignment, a total of 64 2x2 groups of the individual mirrors ES, i.e. 64 second facets 23ᵢ, are present in the form of an 8x8 structure on the individual mirror unit 47.

This subdivision into the rows/columns 48/49 makes it possible to separate contributions from measurement light individual beams 25ᵢ, 25ᵢ₊₁ which are reflected from adjacent ones of the second facets 23ᵢ, by the detection device 28, 34 and/or 37 of the measurement systems explained above.

Each of the 2x2 groups of the individual mirrors ES impinged on by the measurement light 25 can have a surface area which is smaller than a diameter of a source image of the respective light source 3, 32. These source images are cut off marginally at the adjacent rows/columns 48/49 that are not impinged on for guiding the used measurement light 25, and are carried away such that they do not reach the detection device of the respective measurement system. This makes it possible to predefine a large number of different measurement light individual beams 25ᵢ which can be simultaneously separated well by the detection device.

FIG. 14 shows a further embodiment of an individual mirror unit 50, which can be used instead of the individual mirror unit 47 according to FIG. 13. Components and functions corresponding to those which have already been explained above with reference to the aforementioned Figures and for example with reference to FIG. 13 bear the same reference signs and will not be discussed in detail again.

The individual mirror unit 50 according to FIG. 14 is subdivided into 11x11 individual mirrors ES, which once again in a 2x2-grouped arrangement of second facets 23ᵢ each guide one of the measurement light individual beams 25ᵢ. Once again rows 48 and columns 49 of individual mirrors ES not used for guiding the measurement light individual beams 25ᵢ are present between these 2x2 groups, in accordance with the assignment used for a respective measurement, set by way of the individual mirror selection device 30.

The individual mirror unit 50 can have x/y dimensions corresponding to those of the individual mirror unit 47, such that the individual mirrors ES of the individual mirror unit 50 then have correspondingly larger dimensions than in the case of the individual mirror unit 47.

A total of 16 2x2 individual mirror groups or second facets 23ᵢ are present in the case of the individual mirror unit 50.

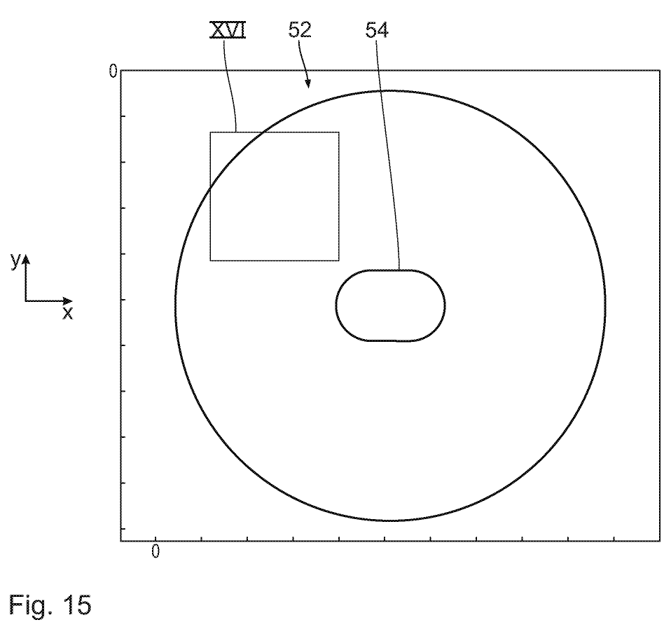

FIG. 15 shows a measurement result of a detection device 28 of the measurement system 24 or respectively 31, recorded with a subdivision of individual mirrors used for guiding the measurement light 25 on the second facet mirror 22 according to FIG. 13.

On account of the arrangement of the sensor array of the detection device 28 in the region of a pupil plane of the optical system of the projection exposure apparatus 1, the measurement result according to FIG. 15 includes imaging information concerning the arrangement of the individual mirrors ES impinged on by the measurement light 25 on the second facet mirror 22.

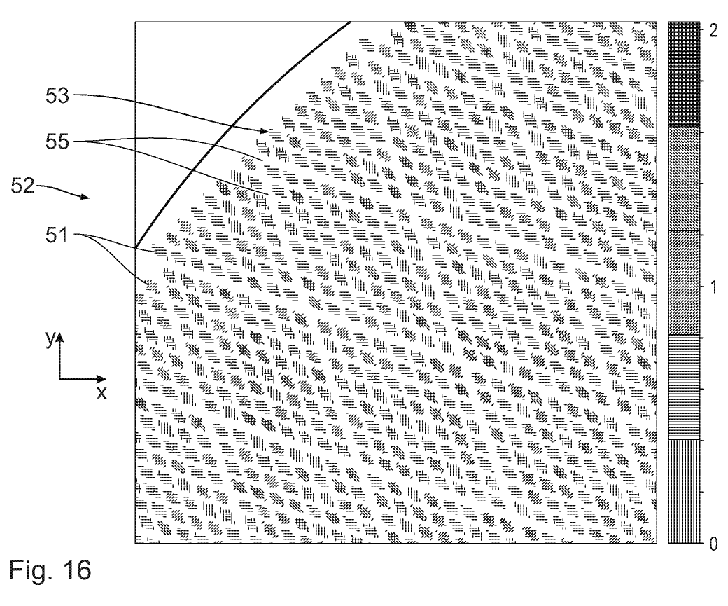

FIGS. 15 and 16 illustrate a distribution of approximately 15000 separated intensity spots 51 on a sensor array 52 of the detection device 28. On account of the imaging properties of the projection optical unit 10, an outer boundary of the second facet mirror 22 on which the measurement light 25 impinges appears round. In addition, an intensity distribution 53 formed by the totality of the intensity spots 51 has an inner obscuration cutout 54 which is stadium-shaped in relation to the x/y-coordinates.

FIG. 16 shows an enlargement of a detail from the intensity distribution 53 in accordance with detail XVI in FIG. 15. In this enlargement of a detail, the individual intensity spots 51 are discernible in a manner well separated from one another. An intensity scale indicated on the right in FIG. 16 shows various hatchings corresponding to increasing measurement light intensities of the intensity spots 51 from the bottom to the top in the scale.

Each intensity spot 51 corresponds to the point of incidence of exactly one measurement light individual beam 25ᵢ on the sensor array, i.e. represents the image of exactly one 2x2 individual mirror group, i.e. one second facet 23ᵢ, of the individual mirror unit 47 according to FIG. 13. For imaging or representation reasons, these images appear rhombically distorted in FIG. 16. This may be owing to the fact that an intervening imaging optical unit has different imaging scales along the x-direction and along the y-direction.

The 8x8 arrangement of the second facets 23ᵢ per individual mirror unit 47 is also discernible as a corresponding 8x8 structure of the intensity spots 51 of the intensity distribution 53. Intensity gaps 55 of the intensity distribution 53 that extend in rows and columns and correspond to the boundaries of the individual mirror units 47 lie between these 8x8 groups of the intensity spots 51.

Using the guiding of the measurement light individual beams 25ᵢ according to FIG. 13, the intensity of each measurement light individual beam 25ᵢ can be captured in parallel with a measurement result by way of a corresponding spotwise evaluation of the intensity distribution 53 according to FIGS. 15 and 16. Depending on whether the measurement system 24 or 31 is employed, this can be used either taking account of influencing parameters of the EUV used light source 3 of the projection exposure apparatus 1 or with the aid of a stable and well-characterized measurement light source 32.

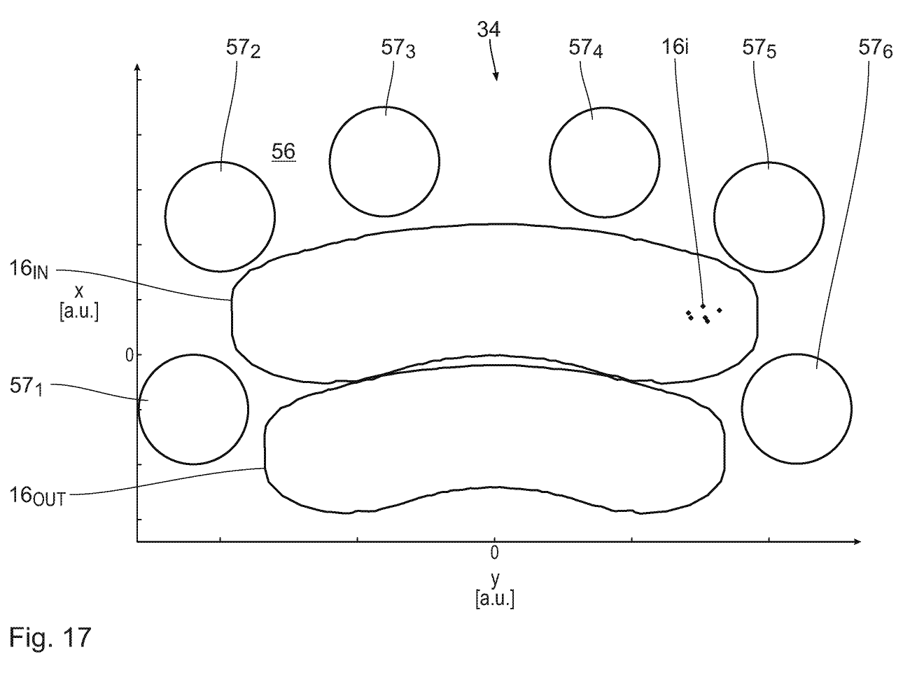

FIG. 17 shows a plan view of the detection device 34 of the measurement systems 33 and respectively 35 in the region of the object field 5. The illustration shows in the plan view exemplary individual beams 16ᵢ of the illumination light 16 within an envelope of a total illumination light beam 16_{IN}, which is guided from the second facet mirror 22 towards the object field 5, and an emerging illumination light beam 16_{OUT} reflected from the object field 5.

FIG. 17 shows a variant of the detection device 34, arranged in an arrangement plane 56, which is illustrated in FIG. 4 and which lies upstream of the object plane 6 in the beam path of the illumination and imaging light 16.

A total of six sensors 57₁ to 57₆ of the detection device 34 lie in the arrangement plane 56. These sensors 57₁ to 57₆ surround beam guiding of the illumination light beams 16_{IN}, 16_{OUT}.

The sensors 57ᵢ are illustrated by circles elucidating a position of a respective pinhole of a pinhole camera of the detection device 34, a sensor array in turn being disposed downstream of each of the pinholes in the measurement light beam path. Instead of a pinhole, in principle, a micromirror, the optical effect of which is then comparable, can also be used at the location of the respective pinhole and guides the measurement light 25 towards a sensor array of the detection device 34, the sensor array then being disposed downstream in the reflected beam path. The diameter of such a pinhole can be in the range of 0.1 mm.

These pinholes can be arranged at the centre of the respective circle of the sensors 57ᵢ. Sensors described in DE 102018207384 B4 can be used, in principle.

The sensors 57ᵢ can include data processing components which are used at least for preprocessing of sensor signals. The pinholes can be at a distance from the object plane 6 in the z-direction. Such a distance can be in the range of between 100 mm and 500 mm, for example in the range of 200 mm to 300 mm, e.g. in the range of 250 mm. A z-extent of the respective sensor 57ᵢ is so small that the sensors in each case overall do not overlap the object plane 6. A z-extent of the respective sensors 57ᵢ is smaller than a distance between the object plane 6 and the arrangement plane 56. The z-extent can be in the range of between 10 mm and 100 mm, for example in the range of between 20 mm and 50 mm.

The sensors 57₁ and 57₂ are displaced in the negative y-direction with respect to the left-hand edge of the illumination light beam 16_{IN}. The sensors 57₅ and 57₆ are correspondingly displaced in the positive y-direction with respect to the right-hand edge of the illumination light beam 16_{IN}. The further sensors 57₃ and 57₄ are displaced in the positive x-direction next to the illumination light beam 16_{IN}.

This arrangement of the sensors 57ᵢ ensures that depending on the tilt angle possibilities of the individual mirrors/second facets 23ᵢ of the second facet mirror 22, it is possible to guide the measurement light individual beams 25ᵢ past the beam path for the used illumination light 16 to in each case at least one of the sensors 57ᵢ. A measurement can then take place by way of the respective measurement system 33 or 35 in parallel with a used mode of operation of the projection exposure apparatus 1, since first the illumination and imaging light beam path and the beam paths of the measurement light individual beams 57ᵢ do not mutually disturb one another.

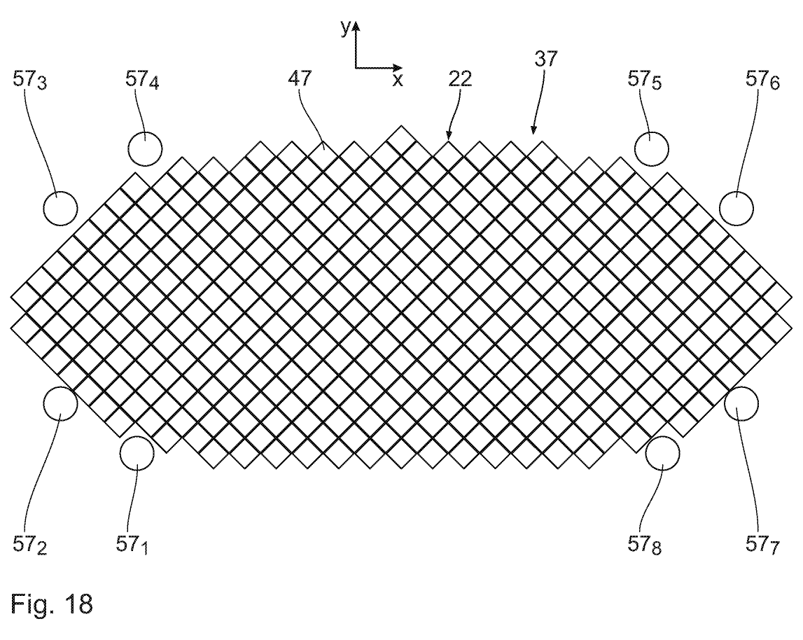

FIG. 18 shows one embodiment of the detection device 37 of the measurement systems 36, 40 according to FIGS. 6 and 7. The illustration schematically shows, in a plan view, the second facet mirror 22 with individual mirror units 47 arranged rhombically in square fashion in this case (cf. FIG. 13). Alternatively, this can also involve an arrangement of monolithic second facets or else a schematic arrangement of individual mirrors.

A total of eight sensors 57₁ to 57₈ of the detection device 37 are arranged around the second facet mirror 22 in the range of larger absolute +/−x-coordinate values. These sensors 57ᵢ according to FIG. 18 are constructed in accordance with those explained above in association with FIG. 17.

The number of sensors 57ᵢ can be in the range of between 1 and 20, for example.

The plurality of sensors 57₁ to 57₈ makes it possible to guide measurement light individual beams 15ᵢ via all individual mirrors/first facets 21ᵢ of the first facet mirror 20 even given the presence of tilt angle limitations of the individual mirrors/first facets 21ᵢ. Even in the case of comparatively small tilt angle amplitudes of the individual mirrors/first facets 21ᵢ which can be reached by way of the actuators 21a, at least one of the sensors 57ᵢ can be reached with a measurement light individual beam 25ᵢ guided via a respective individual mirror/a respective first facet 21ᵢ.

The measurement systems explained above can be used for example for the following measurement methods:

For capturing the far field 44 of the light source 3 and/or for determining an illumination setting set for the two facet mirrors 20, 22 for the purpose of illuminating the object field, i.e. a set illumination intensity distribution and illumination angle distribution of the illumination light 16 over the object field 5, it is possible to use the measurement system 24 or respectively 31 or else the measurement system 33 or 35. The individual mirror selection device 30 selects guidance of the measurement light individual beams 25ᵢ by way of corresponding tilt angle assignment of the actuators 21a, 23a. In the case of the measurement systems 24 and 31, the measurement light individual beams 25ᵢ are imaged into the image field 11 by reflection at a mirror in the object field 5. By this approach, a far field distribution and/or reflectivity properties of the individual mirrors/facets of the two facet mirrors 20, 22 can then be determined, as explained above in association with FIGS. 10 to 16.

Alternatively or additionally, a tilt angle calibration of the individual mirrors/first facets 23ᵢ can be carried out, as explained above in association with FIGS. 8 and 9.

The number of individual mirrors ES on the first facet mirror 20 is regularly much greater than the number of second facets 23 on the second facet mirror 22.

A configuration according to FIG. 13 makes it possible to simultaneously measure a large number of individual mirrors on the first facet mirror 20 by way of corresponding assignment to specific measurement light individual beams 25ᵢ.

When measuring reflectivity properties of the individual mirrors/first facets 21 of the first facet mirror 20 and of the individual mirrors/second facets 23 of the second facet mirror 22, it is also possible to measure tilt-angle-dependent reflectivity properties.

A decision between the properties of firstly a respective individual mirror/a first facet 21 and secondly an individual mirror/a second facet 23 can be taken by way of crosswise assignments of individual mirrors/first facets 21 to different individual mirrors/second facets 23, and vice versa.

In other words, measurements with measurement light individual beams 25ᵢ assigned to different pairings of first facets/individual mirrors 21 and second facets/individual mirrors 23 then take place sequentially.

In a manner analogous to that explained above in association with FIGS. 8 and 9, it is also possible to calibrate tilt angles of the individual mirrors/second facets 23 by a procedure in which, instead of a source image over one of the second facets 23ᵢ, as explained above in association with FIGS. 8 and 9, an image of a first facet 21 is shifted over a pinhole detector in the fashion of the detection device 34. It is then possible to measure a directional accuracy of a tilt angle predefinition of the respective second facet 23ᵢ in rₓ, r_{y}.

For example, an intensity distribution over the far field 44 during a used mode of operation can be measured with the aid of the measurement systems 36, 40. When the measurement system 36 is used, for this purpose individual mirrors/first facets 21 that are not used for generating the respective used illumination setting can be used for guiding the measurement light individual beams 25ᵢ towards the detectors 38ᵢ. When the measurement system 40 is used, in principle all individual mirrors/first facets of the first facet mirror 20 can be used for measurement purposes.

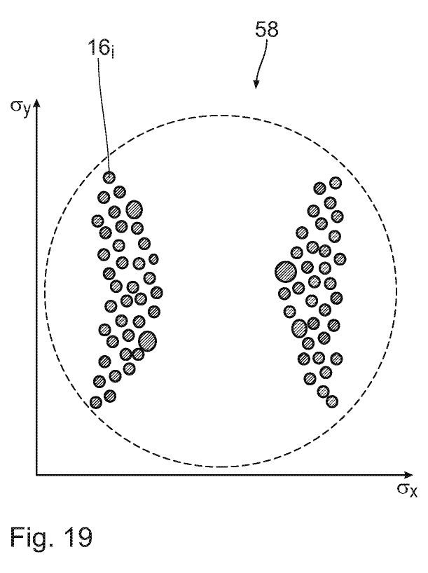

A further application of the measurement systems 24 or 31 for measuring optical surfaces of the mirrors Mᵢ of the projection optical unit 10 is explained below with reference to FIGS. 19 to 23. Components and functions corresponding to those which have already been described above with reference to FIGS. 1 to 18 bear the same reference signs, for example, and will not be discussed in detail again.

FIG. 19 schematically shows an illumination intensity distribution in an illumination pupil 58 of the illumination optical unit 4. Such an illumination pupil 58 can be present in or in the region of an arrangement plane of the second facet mirror 22. A comparable illumination intensity distribution is known from DE 102021213827 A1. The illustration shows a distribution of illumination spots 16ᵢ which belong to different illumination channels of a guidance of the illumination light 16 via the two facet mirrors 20, 22 of the illumination optical unit 4. A size of the illumination spot 16ᵢ respectively illustrated is a measure of the intensity thereof. This illumination intensity distribution is represented in pupil coordinates σₓ, σ_{y}. The illustration additionally shows the illumination intensity distribution which an object point of the reticle 7 experiences integrally during a y-scan through the object field 5, i.e. shows a scan-integrated illumination intensity distribution. This illumination setting according to FIG. 19 is an x-dipole setting.

The illustrated illumination intensity distribution in the illumination pupil 58 corresponds to an illumination angle distribution in the object field 5. The individual illumination spots 16ᵢ differ in their shape, their brightness and also in their extent. Moreover, the individual intensity spots 16ᵢ may also differ in terms of polarization.

Each of these pupil spots 16ᵢ which serves for illuminating the object field 5 from an illumination direction, the position of every pupil spot 16ᵢ in the illumination pupil 58 representing a corresponding illumination angle range, is guided via predefined individual mirrors/a predefined first facet 21 of the first facet mirror 20 and via predefined individual mirrors/a predefined second facet 23ᵢ of the second facet mirror. Reflectivity properties of these individual mirrors/facets which participate in the guidance of the respective partial beams to the illumination spots 16ᵢ of the illumination light 16 can be deduced via the measurement systems 24 or 31. In this case, the reflectivities of the individual mirrors/the first facets 21ᵢ can be separated from those of the individual mirrors/second facets 23ᵢ.

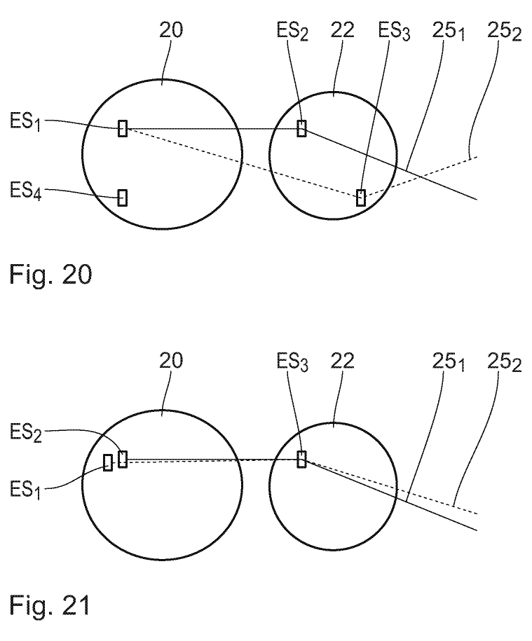

FIGS. 20 and 21 schematically show the guidance of a partial beam 25₁ belonging to an illumination spot 16ᵢ as a solid line and a further partial beam 25₂ as a dashed line via selected individual mirrors ES of the two facet mirrors 20, 22 of the illumination optical unit 4, which are illustrated schematically as circular in plan view in FIGS. 20 and 21.

FIG. 20 shows a measurement example in which a change in reflectivity, for example a decrease in reflectivity, of an individual mirror of the first facet mirror 20 can be deduced. The measurement light individual beam 25₁ is guided via an individual mirror ES₁ of the first facet mirror 20 and via an individual mirror ES₂ of the second facet mirror 22. The measurement light individual beam 25₂ is guided once again via the individual mirror ES₁ of the first facet mirror 20 and via a further individual mirror ES₃ of the second facet mirror 22. The two individual mirrors ES₂, ES₃ of the second facet mirror 22 are spatially at a distance from one another. Insofar as for both measurement light individual beams 25₁ and 25₂ according to FIG. 20 an identical decrease in reflectivity results with regard to the comparison of a measured actual intensity value over the measurement light individual beams 25₁, 25₂ with respect to a predefined target intensity value via the detection device 28, a decrease in reflectivity at the individual mirror ES₁ of the first facet mirror 20 can be deduced from this, since it is unlikely that the two mutually independent individual mirrors ES₂, ES₃ of the second facet mirror 22 will have the same decrease in reflectivity. Such a suspicion that in actual fact the reflectivity of the individual mirror ES₁ has decreased can then be strengthened for example by carrying out a check measurement of further measurement light individual beams 25ᵢ, which are guided via an individual mirror ES₄, which is at a distance from the individual mirror ES₁, of the first facet mirror 20 and once again via the individual mirrors ES₂ and ES₃ of the second facet mirror 22 and are measured via the detection device 28. Here a reflectivity corresponding to a target reflectivity should then result, i.e. no decrease in reflectivity.

FIG. 21 shows a channel assignment for a complementary measurement in which a decrease in reflectivity of an individual mirror of the second facet mirror 22 can be deduced. The two measurement light individual beams 25₁ (solid) and 25₂(dashed) used in this case are guided firstly via two individual mirrors ES₁ and ES₂, which are spatially at a distance from one another, on the first facet mirror 20 and via the same individual mirror ES₃ on the second facet mirror 22. If the detection of the two measurement light individual beams 25₁, 25₂ according to FIG. 21 yields the same decrease in reflectivity, this is indicative of a decrease in reflectivity of the individual mirror ES₃ of the second facet mirror 22.

The measurement light 25 of the measurement light individual beams 25ᵢ, depending on use of the measurement system 24 or 31, can be generated by the light source 3 of the illumination system 2 or by the measurement light source 32 of the measurement system 31.

In a corresponding manner, a reflectivity determining method instead of a measurement of individual mirrors ES can also be achieved by measuring, in regard to reflectivity, the first facets 21 and/or second facets 23 which participate in the guidance of illumination channels. These facets 21, 23, for their part, can be formed from groups of the individual mirrors ES or else be embodied as monolithic facets.

The measurement of the individual mirrors ES or of the facets 21, 23 of the facet mirrors 20, 22 of the illumination optical unit 4 can alternatively also be carried out via the measurement systems 33 and 35 since, for determining the reflectivities of the two facet mirrors 20, 22, it is sufficient to guide the measurement light individual beams 25ᵢ via these components.

A corresponding method can be used for measuring reflectivity distributions over reflection surfaces of the mirrors Mᵢ of the projection optical unit 10. Alternatively or additionally, the method can be used for measuring reflectivity distributions over reflection surfaces of further non-faceted mirrors within the illumination system, for example of deflection mirrors or of mirrors of imaging optical units, e.g. telescope optical units of the illumination optical unit. Such a measurement can also be carried out with the aid of the measurement systems 24 and 31.

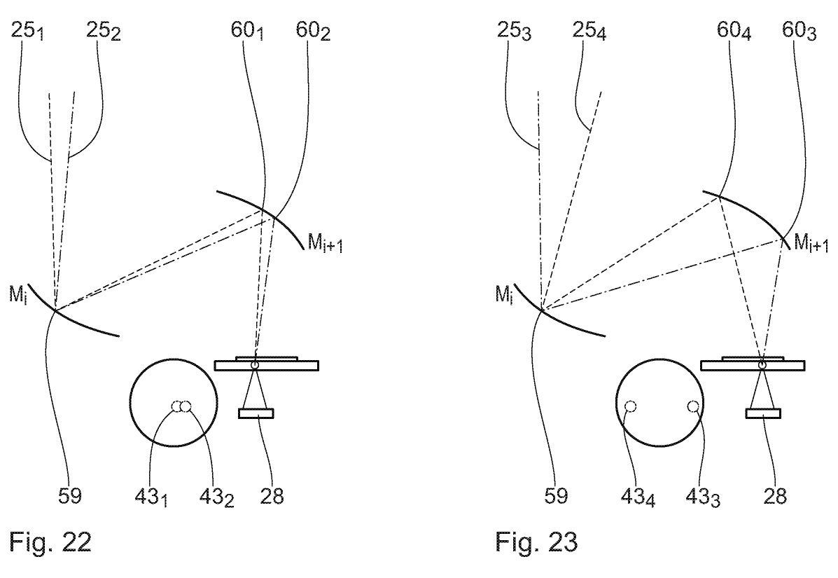

FIG. 22 shows guidance of two measurement light individual beams 25₁ (dashed) and 25₂ (dash-dotted) via two mirrors Mᵢ, Mᵢ₊₁, illustrated by way of example, of the projection optical unit 10. The illustration shows a beam path of these measurement light individual beams 25ᵢ starting from a reflection from a mirror Mᵢ₋₁ – not illustrated in the figures– through to the detection device 28 of the measurement systems 24 or 31.

The measurement light individual beams 25₁ and 25₂ are reflected from the same location 59 on the reflection surface of the mirror Mᵢ in the case of the measurement configuration according to FIG. 22. On the further mirror Mᵢ₊₁ the reflection locations 60₁ and 60₂ are at a close distance from one another.

The mirror Mᵢ₊₁ is a near-pupil mirror of the projection optical unit 10.

The sensor array of the detection device 28 measures two intensity spots 43₁, 43₂at corresponding sensor positions closely adjacent to one another, as illustrated in the insert in FIG. 22.

FIG. 23 shows, for a different channel assignment, different guidance of measurement light individual beams 25₃ (dash-dotted) and 25₄ (dashed), set once again by corresponding selection of the participating individual mirrors/facets of the facet mirrors 20, 22 by way of the individual mirror selection device 30. The two measurement light individual beams 25₃ and 25₄are once again reflected at the same location 59, as in the configuration according to FIG. 22. On the mirror Mᵢ₊₁ the measurement light individual beam 25₃ is reflected at the location 60₃ and the measurement light individual beam 25₄ is reflected at the location 60₄. The two reflection locations 60₃ and 60₄ of the measurement configuration according to FIG. 23 differ from the reflection locations 60₁and 60₂ of the measurement configuration according to FIG. 22.

These measurement light individual beams 25₃ and 25₄ are incident as spaced-apart spots 43₃ and 43₄ on the sensor array of the detection device 28, as illustrated in the insert in FIG. 23.

In line with what has already been explained above in association with FIGS. 20 and 21, by way of a comparison of the intensity measurements of the measurement light individual beams 25₁ to 25₄according to FIGS. 22 and 23, a differentiation is possible as to whether for example a decrease in reflectivity is present at the location 59 of the mirror Mᵢ or at the locations 60ᵢ of the mirror Mᵢ₊₁. In addition, since reflection took place in each case at the same location 59 of the mirror Mᵢ, a reflectivity of the mirror Mᵢ₊₁ can be measured in a spatially resolved manner on the basis of the intensity measurement results of the configurations according to FIGS. 22 and 23. Insofar as, by way of a respective assignment of the individual mirrors/facets 21, 23 by way of the individual mirror selection device 30 upon respective impingement on the location 59, it is possible to cover an entire reflection surface of the mirror Mᵢ₊₁ with respective measurement light individual beams 25ᵢ, an entire reflectivity distribution of the reflection surface of the mirror Mᵢ₊₁ can accordingly be measured.

The mirrors Mᵢ (i = 1... N, N number of mirrors) of the projection optical unit 10 can be measured, in principle, according to the following measurement specification analogously to what has been explained above in association with FIGS. 20 to 24:

For all beam pairs 25ᵢ, 25ⱼ from the set of all possible measurement light individual beams of the system, under the constraint that they have practically an identical incidence location (cf. above, location 59) on one of the mirrors, M₀, the square sum of their distance on all the other mirror surfaces Mᵢ ought to be maximal. For each incidence location of the mirror M₀ each measurement light individual beam 25ᵢ thus acquires a merit function value that qualifies it for its separability quality. A reduction to a minimum number of disjoint configurations of the measurement light individual beams 25ᵢ is thus possible. The disjointness is present on account of the unique identification of a measurement light individual beam 25ᵢ in the pupil measurement as explained above. For this purpose, it is also possible to use a factorization method known from US 8,786,849 B2 and US 2020/0218160 A1.

For assigning measured intensity values to the mirrors Mᵢ it is possible to use a factorization method known from US 8,786,849 B2 and US 2020/0218160 A1.

In order to produce a microstructured component, for example a highly integrated semiconductor component, for example a memory chip, with the aid of the projection exposure apparatus 1, firstly the reticle 7 and the wafer 13 are provided. Subsequently, a structure on the reticle 12 is illuminated by the illumination light 16 using the illumination optical unit 4 and is projected onto a light-sensitive layer on the wafer 13 using the projection optical unit of the projection exposure apparatus 1. By developing the light-sensitive layer, a microstructure is then produced on the wafer 13 and the microstructured or nanostructured component is produced therefrom.

The component produced can be a microchip, for example a memory chip.

What is claimed is:

1. A measurement system, comprising:
a first tilting actuator device comprising a first tilting actuator;
a second tilting actuator device comprising a second tilting actuator;
a first facet mirror comprising individual mirrors tiltable via the first tilting actuator;
a second facet mirror comprising individual mirrors tiltable via the second tilting actuator, the first and second facet mirrors configured to illuminate an object field with illumination light, and the individual mirrors of the second facet mirror configured to image the individual mirrors of the first facet mirror into the object field;
a measurement light beam selection device configured to select a measurement light individual beam guided by at least one of the individual mirrors of the first facet mirror and at least one of the individual mirrors of the second facet mirror;
a detection device configured to detect the measurement light individual beam; and
a control/regulating device signal-connected to the first tilting actuator device, the second tilting actuator device, the measurement light beam selection device and the detection device.

2. The measurement system of claim 1, wherein the measurement light beam selection device is configured to simultaneously select a plurality of measurement light individual beams, each of the measurement light individual beams being guided by exactly one individual mirror of the first facet mirror and at least one individual mirror of the second facet mirror.

3. The measurement system of claim 1, wherein the measurement light beam selection device comprises a reflective micromirror at a measurement field point in the object field.

4. The measurement system of claim 1, wherein the measurement light beam selection device is signal-connected to the control/regulating device so that the measurement light beam selection device selects individual mirrors of the first facet mirror and/or individual mirrors of the second facet mirror that guide the measurement light individual beam.

5. The measurement system of claim 1, wherein the measurement light beam selection device comprises an individual mirror group selection device configured to select groups of individual mirrors of the first facet mirror and/or groups of individual mirrors of the second facet mirror to guide the measurement light individual beam.

6. The measurement system of claim 1, wherein the detection device is in a region of the object field.

7. The measurement system of claim 1, wherein the detection device is in a region of the second facet mirror.

8. The measurement system of claim 1, further comprising an imaging optical unit configured to image the object field into an image field, wherein the detection device is in a region of the image field.

9. The measurement system of claim 1, further comprising a measurement light source configured to generate the measurement light individual beam.

10. The measurement system of claim 1, wherein:
the measurement light beam selection device is configured to simultaneously select a plurality of measurement light individual beams, each of the measurement light individual beams being guided by exactly one individual mirror of the first facet mirror and at least one individual mirror of the second facet mirror; and
the measurement light beam selection device comprises a reflective micromirror at a measurement field point in the object field.

11. The measurement system of claim 1, wherein:
the measurement light beam selection device is configured to simultaneously select a plurality of measurement light individual beams, each of the measurement light individual beams being guided by exactly one individual mirror of the first facet mirror and at least one individual mirror of the second facet mirror; and
the measurement light beam selection device comprises a reflective micromirror at a measurement field point in the object field.

12. The measurement system of claim 1, wherein:
the measurement light beam selection device is configured to simultaneously select a plurality of measurement light individual beams, each of the measurement light individual beams being guided by exactly one individual mirror of the first facet mirror and at least one individual mirror of the second facet mirror; and
the measurement light beam selection device is signal-connected to the control/regulating device so that the measurement light beam selection device selects individual mirrors of the first facet mirror and/or individual mirrors of the second facet mirror that guide the measurement light individual beam.

13. A method, comprising:
providing a measurement system according to claim 1;
selecting a set of measurement light individual beams using the measurement light beam selection device; and
detecting at least one of the selected set of measurement light beam individual beams using the detection device.

14. The method of claim 13, comprising selecting the set of the measurement light individual beams so that the measurement light individual beams impinge on individual mirrors of the first facet mirror, wherein the individual mirrors are distributed over a predefined region of the first facet mirror.

15. The method of claim 13, comprising selecting the set of the measurement light individual beams so that each individual mirror group of the second facet mirror is impinged on by one of the measurement light individual beams, wherein at least one individual mirror which is not impinged on by measurement light which is guided to the detection device remains between two adjacent individual mirror groups respectively impinged on by the measurement light individual beams.

16. The method of claim 13, wherein, during the detection or between successively performed detection steps, at least one individual mirror by which the captured measurement light beam is guided is tilted, wherein detecting is effected in a plurality of tilt positions of the individual mirror.

17. The method of claim 13, wherein the set of the measurement light individual beams is selected or during measurement successive sets of measurement light individual beams are selected such that reflection properties of selected individual mirrors are detected.

18. The method of claim 13, wherein:
the measurement system further comprises an imaging optical unit configured to image the object field into an image field;
the detection device is in a region of the image field; and
the set of the measurement light individual beams is selected or during measurement successive sets of measurement light individual beams are selected such that reflection properties of selected mirrors of the imaging optical unit and/or of the illumination optical unit are detected.

19. A projection exposure apparatus, comprising:
an illumination optical unit;
a projection optical unit; and
a measurement system according to claim 1.

20. A method, comprising:
providing a projection exposure apparatus comprising an illumination optical unit, a projection optical unit and a measurement system according to claim 1;
using the illumination system to illuminate a reticle in an object field of an object plane of the projection optical unit;
using the projection optical unit to image at least a portion of the illuminate reticle onto a light sensitive material in an image field of an image plane of the projection optical unit, the light sensitive material supported by a substrate; and
c) after b), developing the light-sensitive material.
